(19) United States
(12) Patent Application Publication
(10) Pub. No.: US 2004/0023513 A1
(43) Pub. Date: Feb. 5, 2004

(54) Method for manufacturing semiconductor device, substrate treater, and substrate treatment system

(76) Inventors: Shintaro Aoyama, Yamanashi (JP); Hiroshi Shinriki, Yamanashi (JP); Masanobu Igeta, Yamanashi (JP)

Correspondence Address: CROWELL & MORING LLP, INTELLECTUAL PROPERTY GROUP, P.O. BOX 14300, WASHINGTON, DC, 20044-4300, US

(21) Appl. No.: 10/333,406

(22) PCT Filed: Jul. 18, 2001
(86) PCT No.: PCT/JP01/06235

(30) Foreign Application Priority Data
Jul. 21, 2000 (JP) 2000-221172
Jan. 25, 2001 (JP) 2001-17620

(51) Int. Cl. H01L 21/336; B05C 5/00; C23C 16/00; B05C 9/08

(52) U.S. Cl. 438/778; 438/788; 438/287; 118/715; 118/620

(57) ABSTRACT

A radical source is movably provided in a processing vessel holding a substrate, and the location or driving energy of the radical source is set such that the film formed on the substrate has a uniform thickness. Further, a radical source is provided at a first side of the substrate and a radical flow is formed such that the radical flow flows from the first side of the substrate surface to the other side. By optimizing the condition of the radical flow, the film formed on the substrate has a uniform thickness.

### TECHNICAL FIELD

The present invention relates to semiconductor devices, and more particularly to the fabrication process of an ultrafine high-speed semiconductor device having a high-K dielectric film.

With progress in the art of device miniaturization, use of gate length of 0.1 μm or less is becoming possible in modern ultrahigh speed high-speed semiconductor devices. Generally, the operational speed of a semiconductor device is improved with device miniaturization, while in such highly miniaturized semiconductor devices, there is a need of reducing the thickness of the gate insulation film according to scaling low with the device miniaturization, and hence with the reduction of the gate length.

### BACKGROUND ART

In the case the gate length has been reduced to 0.1 μm or less, on the other hand, it is necessary to set the thickness of the gate insulation film to 1-2 nm when SiO₂ is used for the gate insulation film. In such extremely thin gate insulation films, on the other hand, there occurs an increase of tunneling current, and the problem of increase of gate leakage current becomes inevitable.

Under such a situation, there has been a proposal of using a so-called high-K dielectric film having a specific dielectric constant much larger than that of an SiO₂ film and thus capable of realizing a small film thickness in terms of the thickness converted to that of an SiO₂ film while maintaining a large actual film thickness, such as the film of Ta₂O₅, Al₂O₃, ZrO₂, HfO₂, ZrSiO₄ or HfSiO₄, for the gate insulation film. By using such a high-K dielectric film, it becomes possible to use a gate insulation film having a physical thickness of about 10 nm also in an ultrahigh speed semiconductor device having a gate length of 0.1 μm or less, and the gate leakage current formed by the tunneling effect is successfully suppressed.

For Example, it is known that a Ta₂O₅ film substrate can be formed by a CVD process by using Ta(OC₂H₅)₅ and O₂ as gaseous sources. Typically, the CVD process is conducted under a reduced to pressure environment at the temperature of about 48° C. or more. The Ta₂O₅ film thus formed is then annealed in oxygen ambient, and as a result, the oxygen vacancies in the film are eliminated. Further, the film undergoes crystallization. The Ta₂O₅ film thus crystallized shows a large specific dielectric constant.

In a semiconductor device that uses such a high-K dielectric film for the gate insulation film, it is preferable to form the high-K dielectric film directly on a Si substrate for reducing the SiO₂ equivalent thickness of the insulation film. However, in the case the high-K dielectric film is formed directly on the Si substrate, the metal elements in the high-K dielectric film tend to cause diffusion into the Si substrate, and there arises the problem of carrier scattering in the channel region.

From the viewpoint of improving carrier mobility in the channel region, it is preferable to interpose an extremely thin base oxide film having a thickness of 1 nm or less, preferably 0.8 nm or less, between the high-K dielectric gate oxide film and the Si substrate. It should be noted that this base oxide film has to be extremely thin. Otherwise, the effect of using the high-K dielectric film for the gate insulation film would be canceled out. Further, such an extremely thin base oxide film has to cover the surface of the Si substrate uniformly, without forming defects such as interface states.

Conventionally, it has been generally practiced to form a thin gate oxide film by a rapid thermal oxidation (RTO) process of a Si substrate. When to form a thermal oxide film with the desired thickness of 1 nm or less, on the other hand, it is necessary to reduce the process temperature used at the time of the film formation. However, a thermal oxide film thus formed at such a low temperature tends to contain interface states and is deemed inappropriate for the base oxide film of a high-K dielectric gate oxide film.

In the case of a base oxide film, in particular, it has been discovered by the inventor of the present invention that minute fluctuation of thickness of the base oxide film provides a profound effect on the incubation time when a high-K dielectric gate insulation film is formed on such a base oxide film. This means that non-uniformity, or variation of film thickness in the base oxide film may cause serious effect on the high-K dielectric gate insulation film formed thereon and the device characteristic of the semiconductor device may be deteriorated. In view of the situation noted above, it will be understood that the base oxide film formed underneath the high-K dielectric gate insulation film is required not only having a small thickness but also a uniform thickness.

### DISCLOSURE OF THE INVENTION

Accordingly, it is a general object of the present invention to provide a novel and useful substrate processing method wherein the foregoing problems are eliminated.

Another and more specific object of the present invention is to provide a substrate processing method and a substrate processing apparatus capable of forming an insulation film of a predetermined thickness between a substrate and a high-K dielectric gate insulation film with a uniform thickness without forming defects such as interface states.

Another object of the present invention is to provide a fabrication process of a semiconductor device having a structure, in which an oxide film and a high-K dielectric gate insulation film are laminated on a substrate,

wherein the oxide film is formed by the steps of:

supplying a process gas containing oxygen to a substrate surface;

activating said process gas by irradiating said substrate surface with ultraviolet radiation from a ultraviolet radiation source; and

moving said substrate and said ultraviolet radiation source relatively with each other.

Another object of the present invention is to provide a substrate processing apparatus for forming an oxide film between a substrate and a high-K dielectric gate insulation film, comprising:

gas supplying means for supplying a process gas containing oxygen to a substrate surface;

ultraviolet radiation source for activating said process gas by irradiating said substrate surface with ultraviolet radiation; and

optical source moving mechanism for moving said ultraviolet source at a predetermined height over said substrate surface.

Another object of the present invention is to provide a substrate processing system comprising:

a film forming apparatus for forming a high-K dielectric film on a substrate;

a substrate processing apparatus for forming an insulation film on a substrate surface such that said insulation film is sandwiched between said high-K dielectric film and said substrate; and

a vacuum transportation chamber for connecting said deposition apparatus and said substrate processing apparatus by a vacuum ambient, said vacuum transportation chamber including a substrate transportation mechanism,

said substrate processing apparatus comprising:

gas supplying means for supplying a process gas containing oxygen to said substrate surface;

an ultraviolet source for activating said process gas by irradiating said substrate surface with ultraviolet radiation; and

an optical source moving mechanism for moving said ultraviolet source over said substrate surface at a predetermined height.

Another object of the present invention is to provide a substrate processing system comprising:

a substrate processing apparatus for forming an insulation film on the substrate surface;

a plasma nitridation processing apparatus for conducting plasma nitridation processing on said substrate surface; and

a vacuum transportation chamber connecting said deposition apparatus and said substrate processing apparatus by way of vacuum environment, said vacuum transportation chamber including a substrate transportation mechanism,

said substrate processing apparatus comprising:

gas supplying means for supplying a process gas containing oxygen to said substrate surface;

an ultraviolet source for activating said process gas by irradiating said substrate surface with ultraviolet radiation; and

an optical source moving mechanism for moving said ultraviolet source over said substrate surface at a predetermined height.

Another object of the present invention is to provide a method of forming an insulation film on the substrate, comprising the steps of:

supplying a process gas to one or more radical sources;

forming active radicals from said process gas in each of said one or more radical sources;

supplying said active radicals to said substrate surface; and

forming an insulation film by a reaction of said active radicals on said substrate surface, said step of forming said active radicals being conducted by changing a state of each of said one or more radical sources,

said method further comprising:

the steps of obtaining an optimum state in which variation of film state in said insulation film is minimized for each of said one or more radical sources based on the state of said insulation film, and

forming an insulation film on said substrate surface by setting the state of one or more radical sources to said optimum state.

Another object of the present invention is to provide a substrate processing of apparatus for forming an insulation film on a substrate, comprising:

a processing chamber including a stage for holding a substrate;

a plurality of radical sources provided adjacent to said processing chamber at respective locations, each of said radical sources being supplied with a process gas and supplying active radicals to said processing of chamber; and

a radical source setup part setting up the state of said plurality of radical sources,

said radical source setup part setting up the state of said plurality of radical sources such that said insulation film has a uniform film state.

According to the present invention, it becomes possible to optimize the ultraviolet radiation from an ultraviolet source to the substrate surface in a substrate processing apparatus designed for forming an oxide film between a substrate and a high-K dielectric gate insulation film, by providing: gas supplying means supplying a process gas containing oxygen to a substrate surface; an ultraviolet radiation source activating the process gas by irradiating the substrate surface with the ultraviolet radiation; and an optical source moving mechanism moving the ultraviolet source over the substrate surface at a predetermined height. As a result, it becomes possible to form an extremely thin oxide film on the substrate with a uniform thickness. Further, the present invention enables formation of an insulation film of uniform film quality in a substrate processing of apparatus using remote plasma by optimizing of the state of the remote plasma source.

Another object of the present invention is to provide a substrate processing apparatus, comprising:

a processing vessel provided with a stage for holding a substrate;

a process gas inlet provided at a first end of said processing vessel;

an evacuation port provided on said processing vessel at a second end opposite to said first end across said stage;

a radical source provided in said processing vessel at a side closer to said first end as compared with said stage; and

a rotating mechanism for rotating said it stage.

Another object of the present invention is to provide a substrate processing method, comprising the steps of:

rotating a substrate in a processing chamber in which said substrate is provided;

forming a radical flow in said processing chamber such that radicals are caused to flow in said processing chamber along said substrate from a first side to a second side; and

processing a surface of said substrate by said radical flow.

According to the present invention, it becomes possible to conduct a uniform substrate processing on a substrate surface by forming a flow of radicals from the first side to the second side along the surface of a rotating substrate, and by optimizing the flow velocity of the radical flow.

Other features and advantages of the present invention will become apparent from the detailed explanation of preferred embodiments of the invention provided hereinafter with reference to the drawings.

### BRIEF DESCRIPTION OF THE DRAWINGS

FIG. 1 is a diagram showing the construction of a semiconductor device having a high-K dielectric gate insulation film;

FIG. 2 is a diagram explaining the principle of the present invention;

FIG. 3 is a of a diagram showing the construction of a substrate processing apparatus according to a first embodiment of the present invention;

FIGS. 4A-4C are diagrams showing the distribution of film thickness of an oxide film formed by the substrate processing apparatus of FIG. 3;

FIG. 5 at is a diagram showing the relationship between the process time and film thickness for an oxide film formed by the substrate processing apparatus of FIG. 3;

FIGS. 6A-6E are other diagrams showing of the film thickness distribution of the oxide film formed by the substrate processing apparatus of FIG. 3;

FIGS. 7A-7E are further diagrams showing of the film thickness distribution of the oxide film formed by the substrate processing apparatus of FIG. 3;

FIGS. 8A and 8B are diagrams showing the film thickness distribution of the an oxide film according to a comparative example;

FIG. 9 is a flow chart showing the procedure for determining the optimum scanning region according to a first embodiment of the present invention;

FIG. 10 is a flow chart showing the procedure of determining the optimum drive energy of the optical source according to the first embodiment of the present invention;

FIG. 11 is a diagram showing the construction of a cluster type substrate processing apparatus according to a second embodiment of the present invention;

FIG. 12 is a diagram showing the construction of a cluster type substrate processing apparatus according to a third embodiment of the present invention;

FIG. 13 is a diagram showing the construction of a semiconductor device fabricated by the substrate processing apparatus of FIG. 12;

FIG. 14 is a diagram showing a modification of the substrate processing apparatus of FIG. 3;

FIGS. 15A and 15B are diagrams showing a further modification of the substrate processing apparatus of FIG. 3;

FIG. 16 is a diagram showing further modification of the substrate processing apparatus of FIG. 3;

FIG. 17 is a diagram showing the relationship between the oxide film thickness formed by ultraviolet activated oxidation processing and the ultraviolet radiation dose according to a fourth embodiment of the present invention;

FIGS. 18A-18F are diagrams showing the oxide film thickness distribution on the substrate for each of the specimens obtained in the experiment of FIG. 17;

FIG. 19 is a diagram explaining the mechanism of formation of stepped pattern shown in FIG. 17;

FIGS. 20A and 20B are diagrams showing the distribution of ultraviolet radiation intensity on the substrate for the case the substrate processing apparatus of FIG. 16 is applied for a wafer of 300 mm diameter;

FIGS. 21A and 21B are diagrams showing a substrate processing apparatus and intensity distribution of ultraviolet radiation according to a fifth embodiment of the present invention;

FIG. 22 is a diagram showing the construction of substrate processing apparatus according to a sixth embodiment of the present invention;

FIG. 23 is a diagram showing the intensity distribution of ultraviolet radiation in the substrate processing apparatus of FIG. 22;

FIG. 24 is a diagram showing the construction of a substrate processing apparatus according to a seventh embodiment of the present invention;

FIG. 25 is a diagram showing the intensity distribution of the ultraviolet radiation in the substrate processing apparatus of FIG. 24;

FIG. 26 is a diagram showing in the construction of one substrate processing apparatus according to an eighth embodiment of the present invention;

FIG. 27 is an oblique view diagram showing a part of the substrate processing apparatus of FIG. 26 in an enlarged scale;

FIG. 28 is a diagram showing that intensity distribution of ultraviolet radiation in the substrate processing of apparatus of FIG. 26;

FIGS. 29A and 29B are diagrams showing the construction of a conventional substrate processing apparatus that uses a remote plasma source and the problem thereof;

FIG. 30 is a diagram showing the construction of a conventional remote plasma source;

FIGS. 31A and 31B are diagrams showing the construction of a substrate processing apparatus according to embodiments of the present invention;

FIGS. 32A and 32B are diagrams showing an example of substrate processing conducted by the substrate processing apparatus of FIGS. 31A and 31B;

FIG. 33 is a diagram showing the procedure of optimization of the substrate processing apparatus of FIGS. 31A and 31B;

FIG. 34 is a diagram showing the mechanism provided for conducting the optimization procedure of FIG. 33;

FIG. 35 is another diagram showing the optimization-procedure of the substrate processing apparatus of FIGS. 31A and 31B;

FIG. 36 is a diagram showing the construction for conducting the optimization of FIG. 35;

FIGS. 37A and 37B are diagrams showing a modification of the ninth embodiment of the present invention;

FIG. 38 is a diagram showing another modification of the ninth embodiment of the present invention;

FIG. 39 is a diagram showing the construction of a substrate processing apparatus according to a 10th embodiment of the present invention;

FIG. 40 is a diagram explaining the principle of the substrate processing apparatus of FIG. 39;

FIGS. 41A and 41B the sum are other diagrams explaining the principle of the substrate processing apparatus of FIG. 39;

FIGS. 42A and 42B are other diagrams explaining the principle of the substrate processing apparatus of FIG. 39;

FIGS. 43A and 43B are other diagrams explaining the principle of the substrate processing apparatus of FIG. 39;

FIGS. 44A and 44B are diagrams showing an example of film formation by the substrate processing apparatus of FIG. 39;

FIGS. 45A and 45B are diagrams showing the construction of a substrate processing of apparatus according to an eleventh embodiment of the present invention;

FIG. 46 is a diagram showing a modification of the substrate processing apparatus of FIGS. 45A, B;

FIG. 47 is a diagram showing the construction of a substrate processing apparatus according to a twelfth embodiment of the present invention;

FIG. 48 is a diagram showing the construction of a cluster type substrate processing system that uses the substrate processing apparatus of FIG. 47;

FIG. 49 is a diagram showing the construction of a semiconductor device formed by the substrate processing apparatus of FIG. 47;

FIG. 50 is a flow chart showing the process flow of forming the semiconductor device of FIG. 49 by using the cluster type substrate processing system of FIG. 48; and

FIG. 51 is a diagram showing the control timing of the substrate processing apparatus corresponding to the process flow of FIG. 50.

### BEST MODE OF IMPLEMENTING THE INVENTION

[Principle]

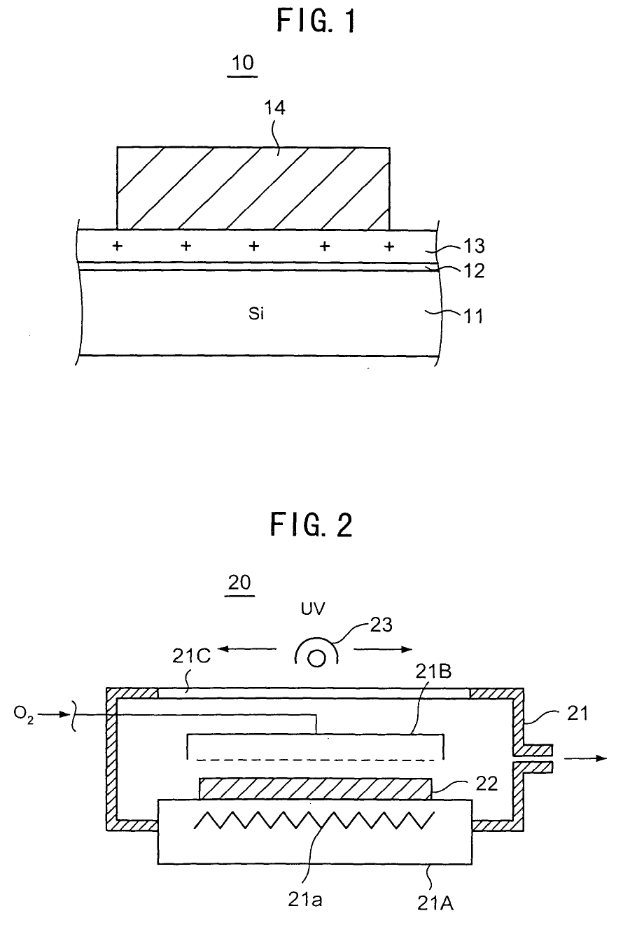

FIG. 1 shows the construction of a high-speed semiconductor device 10 having a high-K dielectric gate insulation film, while FIG. 2 shows the principle of the present invention used for fabricating the semiconductor device of FIG. 1.

Referring to FIG. 1, the semiconductor device 10 is constructed on a Si substrate 11 carrying thereon a high-K dielectric gate insulation film 17 such as Ta₂O₅, Al₂O₃, ZrO₂, HfO₂, ZrSiO₄, HfSiO₄, and the like, via an intervening thin base oxide film 12, and a gate electrode 14 is formed on the foregoing high-K dielectric gate insulation film 13.

As explained before, it is preferable that the base oxide is formed as thin as possible in such a high speed semiconductor device 10, and thus, the base oxide film 12 is typically formed with a thickness of 1 nm or less, preferably 0.8 nm or less. On the other hand, it is required that the base oxide film 12 covers the surface of the Si substrate uniformly with a uniform thickness.

FIG. 2 shows the schematic construction of a substrate processing apparatus 20 used for forming the base oxide film 12 on the Si substrate 11 with a uniform thickness.

Referring to FIG. 2, the substrate processing apparatus includes a processing vessel 21 for holding a substrate 22 to be processed under a reduced pressure environment, wherein the substrate 22 is held on a stage 21A provided with a heater 21. Further, there is provided a shower head 21B in the processing vessel 21 so as to face the substrate 22 held on the stage 21, and an oxidizing gas such as 0₂, 0₃, N₂O, NO or a mixture of thereof, is applied to the showerhead 21B.

The showerhead 21B is formed of a material transparent to ultraviolet radiation such as quartz, and there is provided a window 21C of a material such as quartz transparent to the ultraviolet radiation on the processing vessel 21, such that the window 21C exposes the substrate 22 on the stage 21A. Further, there is provided an ultraviolet optical source 23 outside the window 21C so as to be moveable along the surface of the window 21C.

Thus, a Si substrate is introduced into the processing vessel 21 as the substrate 22, and an oxidizing gas such as O₂ is introduced after evacuating the interior of the processing of vessel 21. Further, by driving the ultraviolet source 23, active radicals such 0* are formed in the oxidizing gas. It should be noted that such the radicals thus activated by the ultraviolet radiation oxidize the exposed surface of the Si substrate 22, and as a result, there is formed an extremely thin oxide film having a thickness of about 0.5-0.8 nm on the surface of the Si substrate 22.

In the present invention, it is possible to form the oxide film with uniform thickness by moving the ultraviolet source 23 along the optical window 21C according to a predetermined program. More specifically, it is possible to compensate for any non-uniformity of film thickness by controlling the position of the ultraviolet source 23 to an optimum substrate region or by controlling the drive energy of the ultraviolet source 23 to an optimum energy level discovered experimentally in advance, even in such a case the oxide film tends to show a reduced thickness in a particular region of the substrate 22 due to the character of the apparatus. Thus, it becomes possible to suppress the problem of variation of film thickness of a high-K dielectric gate insulation film in the case a high-K dielectric gate insulation film is deposited on such oxide film, and a semiconductor device having a stable characteristic is obtained.

Because the oxide film is thus formed by the ultraviolet activate oxidation process, the oxide film contains little interface states as is reported by Zhang, et al. (Zhang, J-Y, et al., Appl. Phys. Lett. 71(20), Nov. 17, 1997, pp.2964-2966), and the oxide film is suitable for the base oxide film 12 provided underneath the high-K dielectric gate insulation film shown in FIG. 1.

[First Embodiment]

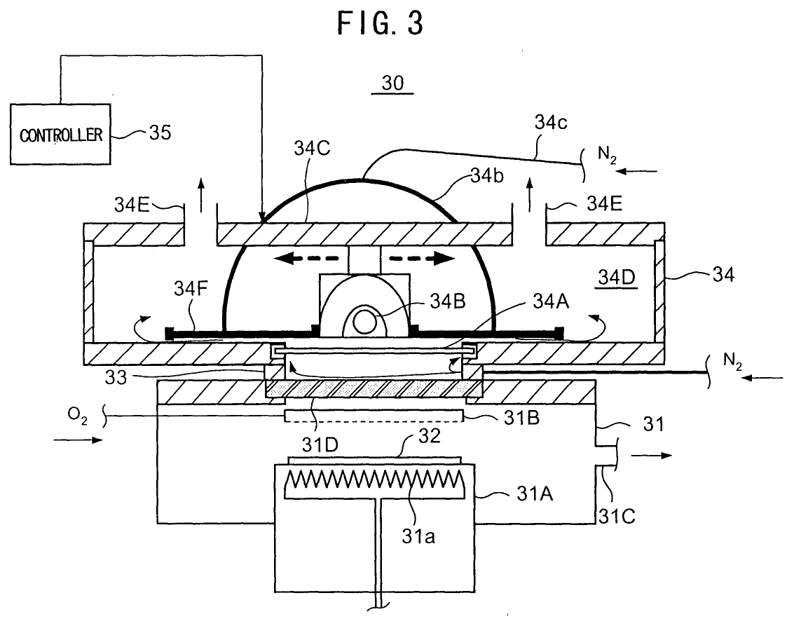

FIG. 3 shows the construction of the substrate processing apparatus 30 according to a first embodiment of the present invention.

Referring to FIG. 3, the substrate processing apparatus 13 includes a processing vessel 31 having a stage 31A holding substrate 32 to be processed thereon, and there is provided a showerhead 31B of a material such as quartz transparent to ultraviolet radiation. The showerhead 31B is provided so as to face the substrate on the stage 31A. Further, the processing vessel 31B is evacuated through an evacuation port 31C, and an oxidizing gas such as O₂ is supplied to the foregoing showerhead 31B from an external gas source.

It should be noted that the processing vessel 31 is formed with an optical window 31B of a material transparent to ultraviolet radiation such as quartz above the showerhead 31B such that the optical window 31B exposes the showerhead 31B and the substrate 32 underneath the showerhead 31B. Further, the stage 31A is provided with a heater 31a for heating the substrate 32.

Further, there is provided an ultraviolet exposure apparatus 34 above the processing vessel 31 via an intervening connection part 33 provided in correspondence to the optical window 31D.

The ultraviolet exposure apparatus 34 includes a quartz optical window 34A corresponding to the optical window 31D and an ultraviolet source 34B radiating ultraviolet radiation upon the substrate 32 via the optical window 31D, wherein the ultraviolet source 34B is held by a robot 34C movably in a direction parallel to the optical window 34A as is represented in FIG. 3 by an arrow. In the illustrated example, the ultraviolet source 34B is formed of a linear optical source extending in the direction generally perpendicular to the moving direction of the ultraviolet source 34B. For such a linear optical source, it is possible to use an excimer lamp having a wavelength of 172 nm.

In the construction of FIG. 3, it should be noted that an inert gas such as N₂ is supplied to the connection part 33 from an external gas source (not shown) via a line 33A for avoiding the problem of absorption of the ultraviolet radiation by the oxygen in the air before the ultraviolet radiation formed by the ultraviolet radiation source 34B is introduced into the processing vessel 31 through the optical window 31D. The foregoing inert gas flows into the space 34D inside the ultraviolet exposure apparatus 34 through a gap formed in the mounting part of the optical window 34A of the ultraviolet exposure apparatus 34.

Further, in order to suppress the incoming flow of oxygen in the air into the region right underneath the ultraviolet source 34B with the driving of the ultraviolet source, there is provided a shielding plate 34F at both lateral sides of the ultraviolet source 34B, and an inert gas such as N₂ is supplied into a narrow region, which is formed between the optical window 34A opposing the ultraviolet source 34B and the shielding plate 34F with a height of about 1 mm or so, via a line 34b. This region is also supplied with the inert gas from the line 33A, and as a result, oxygen absorbing the ultraviolet radiation is effectively purged from this region.

The inert gas passed through the region underneath the shielding plate 34F is caused to flow into the foregoing space 34D and is then discharged to the outside of the ultraviolet exposure apparatus 34 through an evacuation port 34B formed in the ultraviolet exposure apparatus 34.

In the substrate processing apparatus of FIG. 3, it is possible to control the movement and scanning of the ultraviolet source 34B by the robot 34C of the ultraviolet exposure apparatus 34, and as a result, it becomes possible to control the film thickness distribution at the time of formation of the oxide film on the surface of the substrate 32 by the ultraviolet-activated oxidation processing, by controlling the a ultraviolet radiation dose. Further, it should be noted that the controller 35 controls the driving of the ultraviolet source 34B.

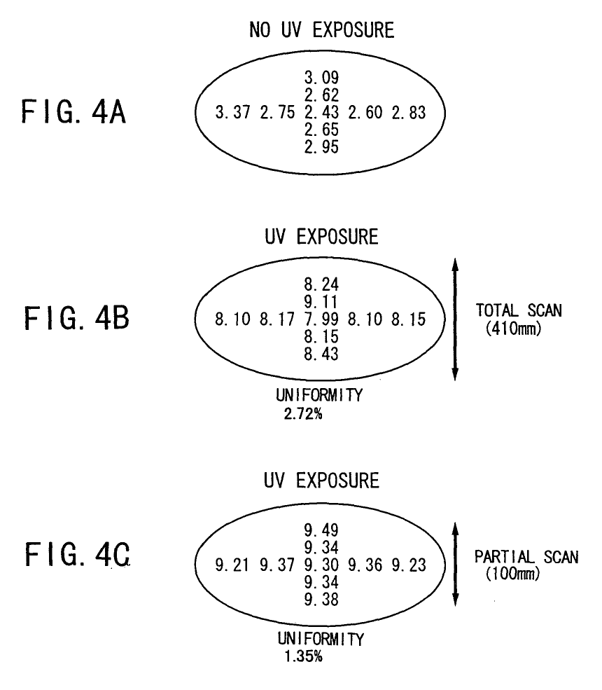

FIGS. 4A-4C show the thickness distribution of the SiO₂ film for the case the SiO₂ film is formed on an Si substrate by using the substrate processing apparatus 30 of FIG. 3 under various conditions, wherein FIGS. 4A-4C show the film thickness in terms of Angstroms. In FIGS. 4A-4C, it should be noted that an 8-inch Si substrate is used for the substrate 32 in the state the native oxide film is removed by a surface pre-processing step, which will be explained later. In each of FIGS. 4A-4C, the internal pressure of the processing vessel 31 is set to 0.7 kPa (5 Torr) and the substrate temperature is set to 300° C.

It should be noted that the illustrated result is for the case O₂ is supplied into the processing vessel 31 with the flow rate of 1SLM for 5 minutes, wherein FIG. 4A shows the case in which no ultraviolet irradiation has been made, while FIGS. 4B and 4C show the cases in which the ultraviolet radiation applied with a dose of 30 mW/cm² when measured in the part right underneath the optical source. It should be noted that FIG. 4B shows the case in which the ultraviolet optical source 34B has scanned the range of 410 mm, so that the entire surface of the substrate 32 is uniformity exposed.

Referring to FIG. 4A, it will be noted that the SiO₂ film formed on the Si substrate surface has the thickness of 0.2-0.3 nm in the case no ultraviolet radiation has been applied. This means that no substantial film formation has been caused in this case. In the case of FIG. 4B, on the other hand, it can be seen that and SiO₂ film of about 0.8 nm thickness is formed on the surface of the Si substrate. Further, in the case of FIG. 4B, it can be seen that the thickness of the SiO₂ film is reduced at the central part of the 8-inch Si substrate 32 even in the case the ultraviolet source 34B has scanned uniformly over the range of 400 mm. As a result, it can be seen that the variance of thickness of the SiO₂ film formed on the Si substrate takes a relatively large value of 2.72%. It is believed that this reflects the characteristic pertinent to the particular substrate processing apparatus 30 used for the experiment.

FIG. 4C, on the other hand, shows the thickness distribution of the SiO₂ film for the case the scanning of the ultraviolet source 34B is made in a limited range of 100 nm at the central part of the Si substrate 32.

Referring to FIG. 4C, it can be seen that the thickness of the SiO₂ film thus formed falls in the range of 0.92-0.93 nm and that the variation of the film thickness has been reduced to 1.35%.

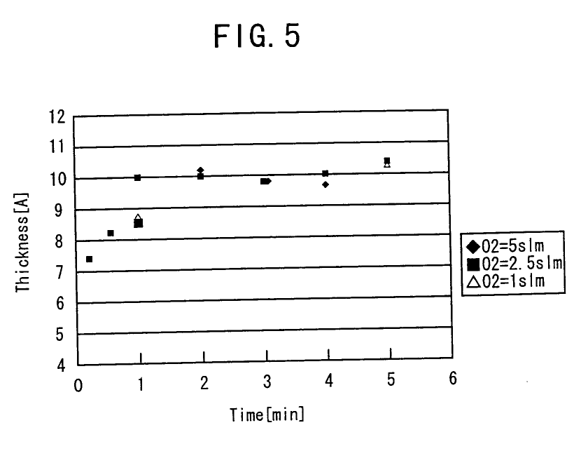

FIG. 5 show the relationship between the ultraviolet exposure time and the thickness of the SiO₂ film for the case the flow rate of O₂ introduced into the processing vessel 31 is changed variously in the experiment of FIGS. 4A-4C.

As can be seen from FIG. 5, the thickness of the SiO₂ film thus formed is substantially irrelevant to the O₂ flow rate and there appears saturation at about 1 nm after the duration of 1 minute. On the other hand, in the case the exposure time is less than 1 minute, the film thickness increases with the exposure time. Thus, FIG. 5 shows that a very short time is sufficient for the formation of the SiO₂ film used for the base oxide film on the surface of the Si substrate when the substrate processing apparatus 30 of FIG. 3 is used.

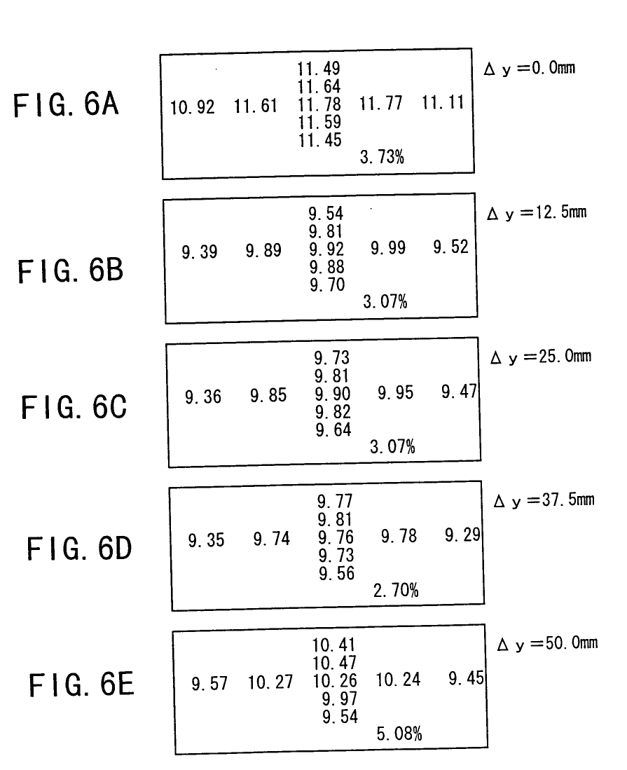

FIGS. 6A-6E show the thickness distribution of the SiO₂ film obtained for the case the ultraviolet source 34B has scanned the area of 100 mm in the substrate processing apparatus of FIG. 3 in the state an O₂ gas is supplied with a flow rate of 1SLM and the processing has been made under the internal pressure of the processing vessel of about 0.7 kPa (5 Torr) at the substrate temperature of 450° C. For the sake of simplicity, the Si substrate is represented by a rectangle in the drawings.

It should be noted that FIG. 6A shows the case in which the scanning has been made over the range of ±50 mm about the center of the substrate, wherein it will be noted that there is a tendency of the SiO₂ film increasing the thickness thereof in the upward direction along the y-axis from the center of the substrate and also in the rightward direction along the x-axis. In this case, the variation of the thickness of the SiO₂ film becomes 3.73%.

On the other hand, FIG. 6B shows the thickness distribution of the SiO₂ film represented in terms of Angstroms for the case the origin of scanning is displaced by 12.5 mm on the y-axis in the downward directions. As can be seen from FIG. 6B, the variation of thickness of the SiO₂ film is reduced to 3.07%.

Further, FIG. 6C shows the thickness distribution of the SiO₂ film represented in terms of Angstroms for the case the origin of scanning has been displaced by 25.0 mm in the downward direction on the y-axis. As can be seen from FIG. 6C, the variation of thickness of the SiO₂ film becomes 3.07%, which is identical with the case of FIG. 6B.

On the contrary, FIG. 6D shows the thickness distribution of the SiO₂ film represented also in terms of Angstroms for the case the origin of scanning is displaced by 37.5 mm on the y-axis in the downward direction from the center of the substrate. As can be seen from FIG. 6D, the variation of thickness of the SiO₂ film is reduced to 2.70%.

Further, as represented in FIG. 6E, the variation of thickness of the SiO₂ film increases to 5.08% in the case the origin of scanning is offset on the y-axis in the downward direction from the center of the substrate by the distance of 50.0 mm.

From these results, it is concluded that the variation of thickness of the SiO₂ film formed on the substrate 32 can be minimized in the substrate processing apparatus 30 of FIG. 3 by optimizing the region of scanning of the ultraviolet source 34B with regard to the substrate.

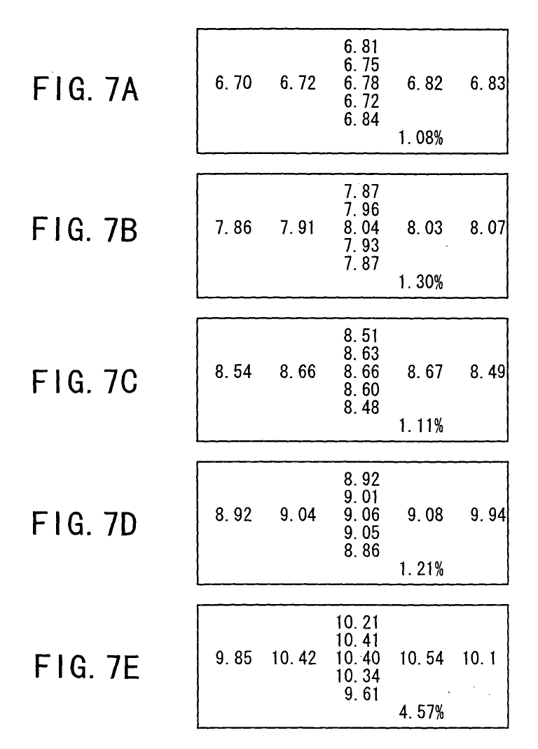

FIGS. 7A-7B show the thickness distribution of the SiO₂ film represented in terms of Angstroms for the case the scanning range of the ultraviolet source 34B is set to 100 mm in the substrate processing apparatus 30 of FIG. 3 and the origin of scanning is offset by 37.5 mm on the y-axis in downward direction from the center of the substrate 32. Here, the SiO₂ film has been formed by setting the radiation dose to any of: 3 mW/cm², 6 mW/cm², 12 mW/cm², 18 mW/cm², and 24 mW/cm².

Referring to FIGS. 7A-7E, it can be seen that that the variation of the film thickness becomes minimum in the case the radiation dose is set to 3 mW/cm² as represented in FIG. 7A and that the variation increases with increasing radiation dose.

The result FIGS. 7A-7E indicates that it is also possible to minimize the variation of film thickness of the SiO₂ film by optimizing the radiation dose of the ultraviolet source 34B in the substrate processing apparatus 30 of FIG. 3.

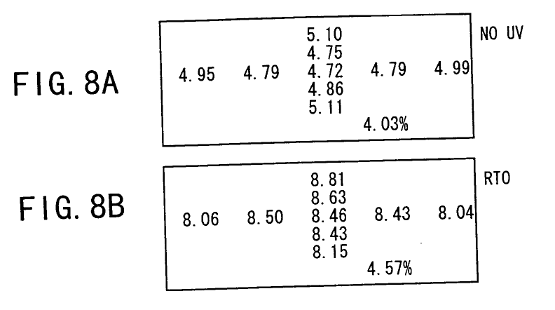

FIGS. 8A and 8B show comparative examples wherein FIG. 8A represents the case of forming an SiO₂ film under the identical condition of FIGS. 7A-7E but without conducting ultraviolet irradiation, while FIG. 8B shows the case of forming an SiO₂ film by a conventional rapid thermal oxidation processing. In any of these cases, it can be seen that the variation of the film thickness exceeds 4%.

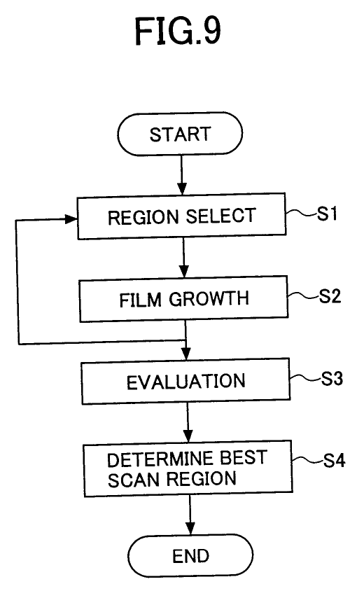

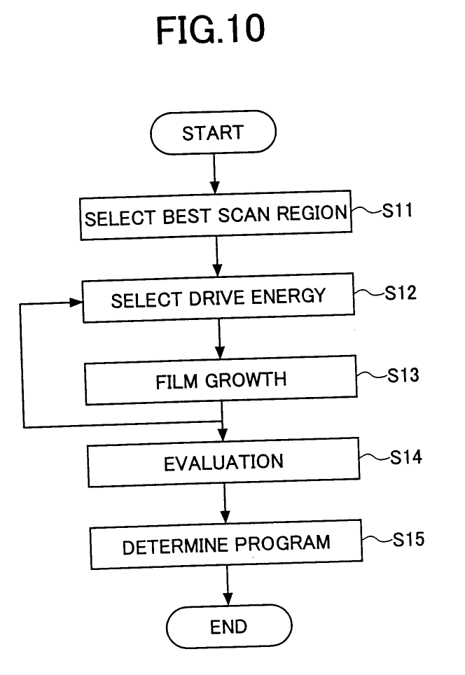

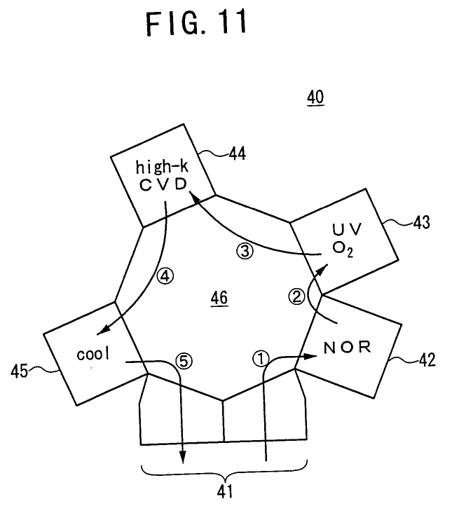

FIGS. 9 and 10 are flow charts used for seeking for the optimum condition of substrate processing in the substrate processing apparatus 30 of FIG. 3 based on the above-mentioned results. Here, it should be noted that FIG. 9 is the flow chart for seeking for the optimum scanning region, while FIG. 10 is the flow chart seeking for the optimum radiation dose.

Referring to FIG. 9, an arbitrary 3 region on the substrate is specified in the first step 1, and in the next step 2, the substrate 32 is introduced into the substrate processing apparatus 30. Thereby, the ultraviolet source 34B is caused to scan over the specified region of the substrate 32, and formation of an SiO₂ film is achieved. Further, by repeating the steps 1 and 2 and by displacing the foregoing region on the substrate 32 each time, a number of SiO₂ films are formed.

Further, the step 3 is conducted for evaluating the distribution of thickness for the SiO₂ films thus obtained in the experiments, and the step 4 is conducted for seeking for the optimum scanning region in which the variation of film thickness becomes minimum.

After the search of FIG. 9 for the optimum scanning condition, a search of optimum irradiation condition shown in FIG. 10 is conducted.

Referring to FIG. 10, the optimum scanning region searched by the procedure of FIG. 9 is specified in the step 11, and the driving energy of the ultraviolet source 34B is specified in the next step 12. Further, in the steps 13, the substrate 32 is introduced into the substrate processing apparatus 30, and the ultraviolet source 34B is caused to scan over the specified region of the substrate 32 with the drive energy specified by the step 12. With this, an SiO₂ film is formed. Further, by repeating of the steps 12 and 13, and by displacing and the driving energy each time, a number of SiO₂ films are formed.

Further, in the step 14, the thickness distribution is evaluated for the SiO₂ films thus obtained in the experiments, and the optimum driving energy of the ultraviolet source 34B that minimizes the thickness of variation is searched. Further, in he step 15, the program controlling the ultraviolet source 34B of said substrate processing apparatus 30 is determined such that the film formation is conducted under such an optimum driving energy.

The controller 35 controls the robot 34C and the ultraviolet source 34B according to the program thus determined, and as a result, an extremely thin and uniform SiO₂ film is formed on the substrate 34 with a thickness of 0.3-1.5 nm, preferably 1 nm or less, more preferably 0.8 nm or less.

[Second Embodiment]

FIG. 11 shows the construction of a substrate processing system 40 according to a second embodiment of the present invention in which the substrate processing apparatus 30 of FIG. 3 is incorporated.

Referring to FIG. 11, the substrate processing system 40 is a cluster type apparatus and includes a load lock chamber 41 used for loading and unloading a substrate, a preprocessing chamber 42 for processing the substrate surface by nitrogen radicals N* and hydrogen radicals H* and an NF3 gas. The preprocessing chamber thereby removes the native oxide film on the substrate surface by converting the same to an volatile film of N—O—Si—H system. Further, the cluster type processing apparatus includes a UV-O₂ processing chamber 43 including the substrate processing apparatus 30 of FIG. 3, a CVD processing chamber 44 for depositing a high K dielectric film such as Ta₂O₅, Al₂O₃, ZrO₂, HfO₂, ZrSiO₄, HfSiO₄, and the like, and a cooling chamber 45 for cooling the substrate, wherein the chambers 41 through 45 are connected with each other by a vacuum transportation chamber 46, and the vacuum transportation chamber 46 is provided with a transportation arm (not shown).

In operation, the substrate introduced via the load lock chamber 41 is forwarded to the preprocessing chamber 42 along a path (1), and the native oxide film is removed therefrom. The substrate 42 thus removed the native oxide film in the preprocessing chamber 42 is then introduced into the UV-O₂ processing chamber 43 along a path (2), and the SiO₂ base oxide 12 shown in FIG. 1 is formed with a uniform thickness of 1 nm or less, by scanning the optimum region of the substrate with the ultraviolet source 34B in the substrate processing apparatus 30 of FIG. 3.

Further, the substrate thus formed with the SiO₂ film in the UV-O₂ processing chamber 43 is introduced into the CVD processing chamber 44 along a path (3), and the high-K dielectric gate insulation film 14 shown in FIG. 1 is formed on the SiO₂ film thus formed.

Further, the substrate is transported from the CVD chamber 44 to the cooling chamber 45 along a path (4) for cooling, and after cooling in the cooling chamber 45, the substrate is returned to the load lock chamber 41 along a path (5) for transportation to the outside.

[Third Embodiment]

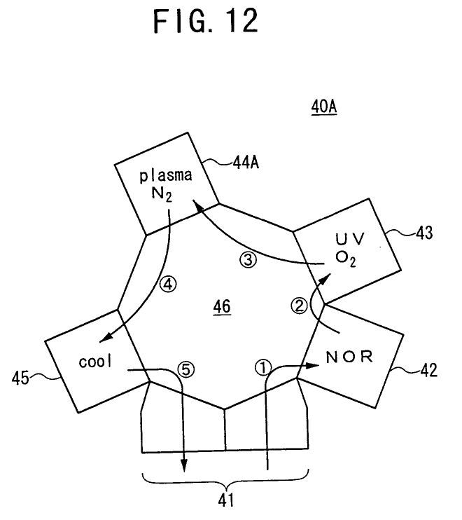

FIG. 12 shows the construction of a substrate processing system 40A according to a third embodiment of the present invention.

Referring to FIG. 12, the substrate processing system 40A has the construction similar to that of the substrate processing system 40 except that there is provided a plasma nitridation processing chamber 44A in place of the CVD processing chamber 44.

The plasma nitridation processing chamber 44A is supplied with the substrate formed with the SiO₂ film in the UV-O₂ processing chamber 43 along a path (3), and a SION film is formed on the surface thereof by plasma nitridation processing.

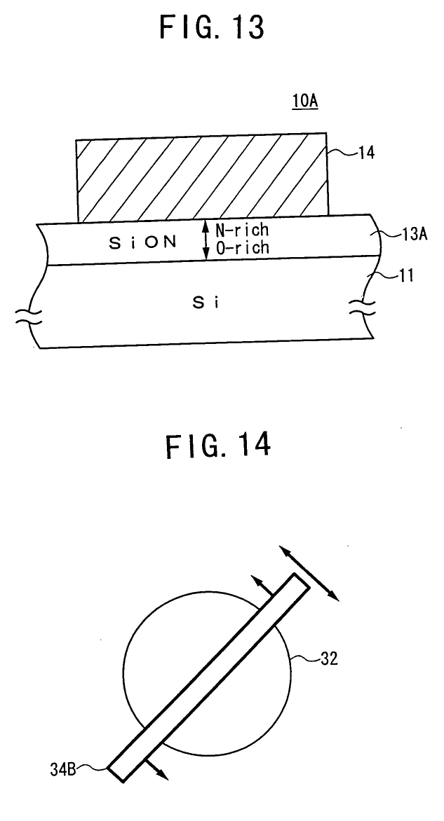

By repeating such process steps between the UV-O₂ processing chamber 43 and the plasma nitridation processing chamber 44A, a semiconductor device 10A having a SiON gate insulation film 13A shown in FIG. 13 is obtained. In FIG. 13, it should be noted that those parts explained previously are designated by the same reference numerals and the description thereof will be omitted.

In the structure 10A of FIG. 13, the SiON gate insulation film 13A is formed with the thickness of 1.5-2.5 nm, wherein it is possible to form the SiON gate insulation film 13A with a compositional gradient such that the bottom part thereof is enriched with O and the top part thereof is enriched with N.

[Modification]

In the substrate processing apparatus 30 of FIG. 3, it should be noted that the movement of the linear ultraviolet source 34B is not limited to the back and forth movement in the direction represented in FIG. 3 by arrows but it is also possible to rotate the substrate 32 and combine the back-and-forth movement therewith as represented in FIG. 14. Further, such a rotation of the optical source 34B with respect to the substrate 32 may be at achieved by rotating the optical source 34B itself or by a rotating of the substrate 32.

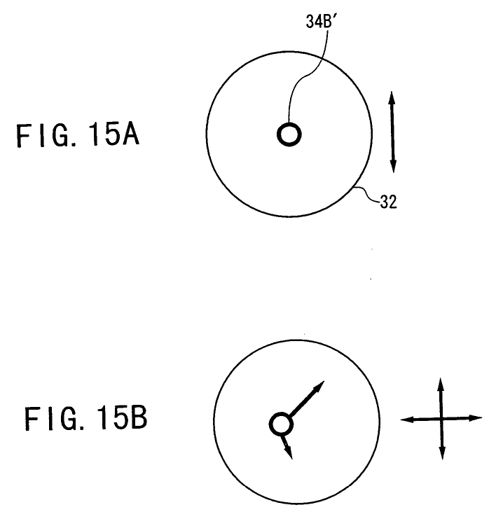

Further, in the substrate processing apparatus 30 of FIG. 3, it is also possible to use a point-like ultraviolet source 34B′ as represented in FIG. 15A in place of the linear ultraviolet optical source 34B, and move such a point-like ultraviolet source 34B′ in the vertical and horizontal directions on the substrate 32 as represented in FIG. 15B.

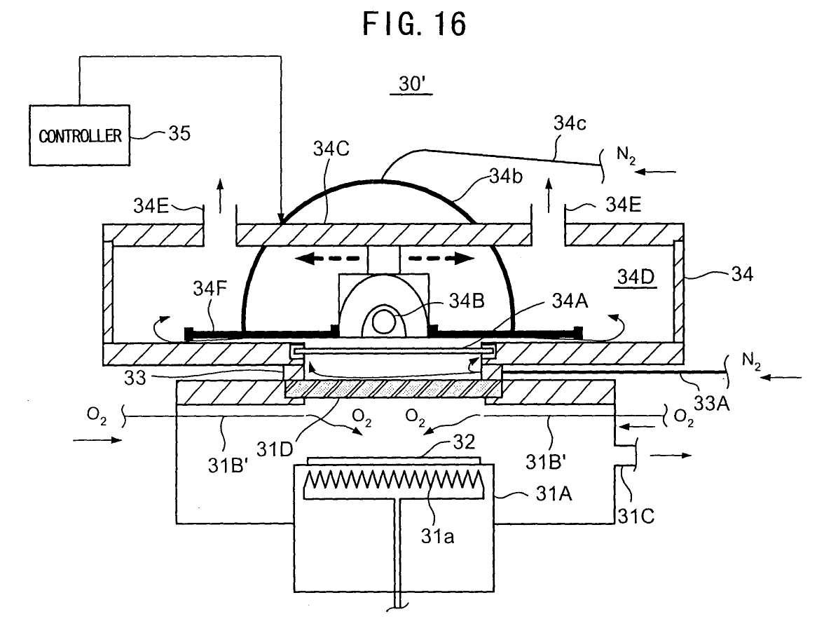

FIG. 16 shows a substrate processing apparatus 30₁ according to another modification of the substrate processing apparatus 30 of FIG. 3, wherein those parts explained previously are designated by the same reference numerals and the description thereof will be omitted.

Referring to FIG. 16, the quartz showerhead 31B is removed in the substrate processing apparatus 30₁ and there are provided a plurality of gas inlets 31B′ in the processing vessel 31 for introducing O₂ such that the gas inlets 31B′ avoid the region on the substrate 32. Further, in the construction of FIG. 14, it should be noted that the quartz window 34A formed in the connection part 43 in correspondence to the ultraviolet exposure apparatus 34 in the construction of FIG. 3 is removed.

According to such a construction the absorption of the ultraviolet radiation formed by the ultraviolet source 34B by the quartz window 34A or the showerhead 31B becomes minimum.

In the construction of FIG. 3 or FIG. 16, it is also possible to connect an evacuation duct to the evacuation port 34B according to the needs and discharge the exhaust of the ultraviolet exposure apparatus 34 to the environment after scrubbing.

[Fourth Embodiment]

The inventor of the present invention has conducted an experiment of forming a SiO₂ film on a (100) surface of the Si substrate by using the substrate processing apparatus 30 explained previously with reference to FIG. 3 while changing the driving power of the ultraviolet optical source 34B and measuring the films thickness of the SiO₂ film thus obtained by an XPS (X-ray photoelectron spectroscopy) method. By conducting the film thickness measurement by XPS, it becomes possible to eliminates the effect of apparent change of film thickness of the SiO₂ film caused by the adsorbents (H₂O or organics) contained in the air and adsorbed on the film surface as compared with the case of using ellipsometry, in which the film thickness measurement is conducted in the air. Thereby, more accurate measurement of film thickness becomes possible.

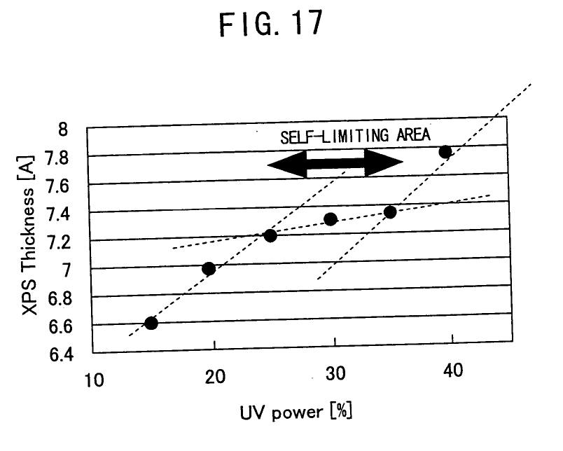

FIG. 17 shows the relationship between the film thickness of the SiO₂ film thus obtained and the ultraviolet optical power. It should be noted that the experiment of FIG. 17 is conducted for the case the power of the ultraviolet radiation is changed with the respect to a reference luminance of 50 mW/cm² realized in the region right underneath the optical source, within the range of 10-45%. Here it should be noted that the oxidation is conducted for the duration of 5 minutes. Further, it should be noted that the location of the optical source 34B is optimized according to the procedure explained with reference to FIG. 9 in the experiment of FIG. 17.

Referring to FIG. 17, it can be seen that the thickness of the SiO₂ film as measured by the XPS method increases generally linearly from 0.66 nm to 0.72 nm with the luminance of the ultraviolet radiation in the case of the luminance is in the range of about 15-25% of the foregoing reference luminance. Further, it can also be seen that the film thickness increases generally linearly in the case the luminance is the in the range of about 35% to 40% of the reference luminance. Further, it can be seen from FIG. 17 that the thickness of this SiO₂ film changes only 0.01 nm from the thickness of 0.72 nm to 0.73 nm in the case with the luminescence of the word ultraviolet source is in the range of about 25-35% of the reference luminance.

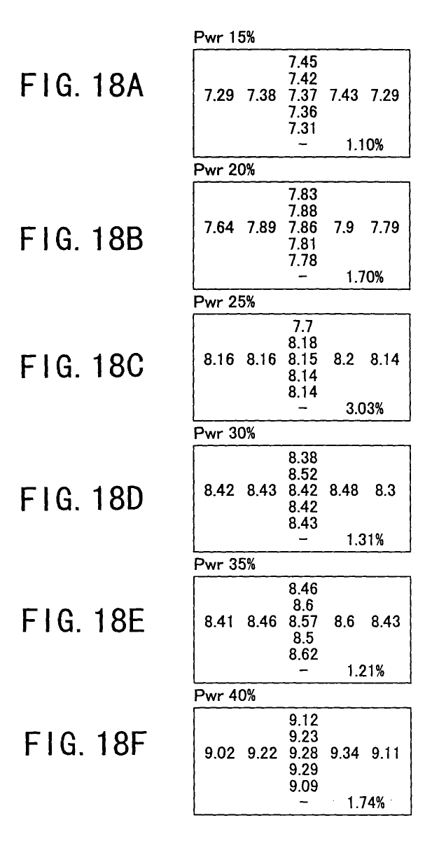

FIGS. 18A-18F show the thickness distribution of the SiO₂ film formed by the ultraviolet-activated oxidation processing step conducted on the a Silicon substrate used in the experiment of FIG. 17.

Referring to FIGS. 18A-18F, it can be seen that the thickness variation of the SiO₂ film can be suppressed within 2% or less, by reducing the luminance of the ultraviolet radiation such that that the SiO₂ film is formed with the thickness of 1.0 nm or less, except for the case of FIG. 18C of setting the luminance to 25% of the reference luminance. Particularly, by setting the ultraviolet luminance to 30% or 35% of the reference luminance as represented in FIG. 18D or 18E, in other words, by setting the ultraviolet luminance to the luminance region shown in FIG. 17 in which the increase of the films thickness of the SiO₂ film is small, it is possible to suppress the film thickness variation of the SiO₂ film to 1.21-1.31%.

Such remarkable improvement of uniformity of film thickness variation observed in the case the thickness of the SiO₂ film is reduced to 1.0 nm or less, particularly the step-like change of the SiO₂ film thickness with the ultraviolet radiation dose as observed in FIG. 17, suggests the existence of a self control (self-limiting) effect in the ultraviolet-activated oxidation processing. It is thought that the step-like change of the SiO₂ film thickness observed in FIG. 17, while being observed for the case the ultraviolet radiation power is changed, is also expected observed with regard to the process temperature or process duration.

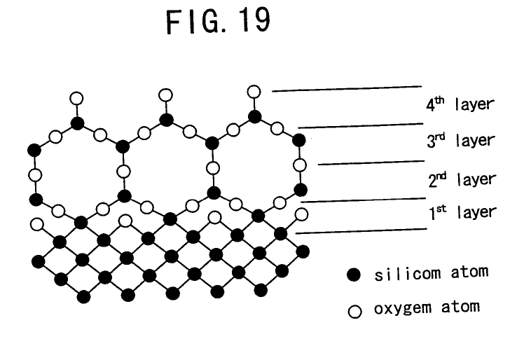

FIG. 19 shows one possible mechanism of such self-limiting effect.

Referring to FIG. 19, an SiO₂ film having a three-dimensional Si—O—Si network is formed on the surface of the Si substrate at the time of the oxidation process as a result of penetration of oxygen, wherein it should be noted that such a progress of oxidation process of the Si substrate starts from the location where the bonding of the Si atoms is weakest. In the case one whole atomic layer of the crystal constituting the substrate is oxidized as in the state of FIG. 19, on the other hand, the number of the sites of the weak bond necessary for causing the oxidation is reduced. Further, it becomes necessary to provide a large amount of activated oxygen in order to start a new oxidation phase in view of the need of the oxygen atoms to penetrate through the oxide film for causing the oxidation and in view of increased thickness of the oxide film. Thus, it is believed that such an increase of the active oxygen associated with the ultraviolet-activated oxidation processing also contributes to the slowdown of the oxide film growth. It is believed that the step-like growth of the oxide film shown in FIG. 17 is caused as a result of the self-limiting effect associated with such atomic layer oxidation during the oxide film growth.

It is believed that the observed uniformity of the oxide film is maintained up to 5-6 layers in terms of the SiO₂ molecular layers.

From the results of FIGS. 17 and 18, it is preferable to conduct the ultraviolet-activated oxidation processing in the substrate processing apparatus 30 of FIG. 3 such that the SiO2 film has a thickness of 5-6 molecular layers or less, preferably 3 molecular layers or less.

[Fifth Embodiment]

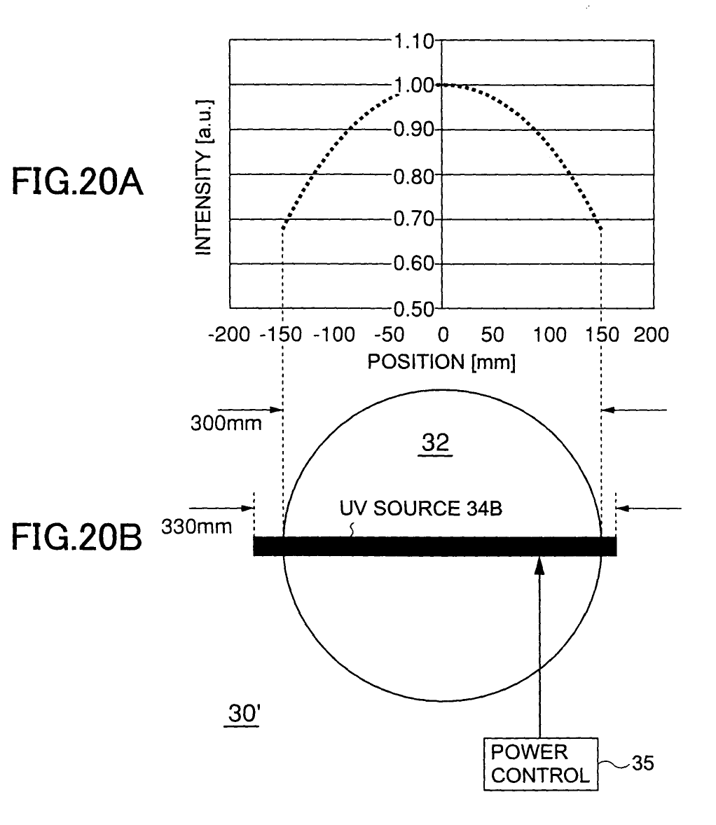

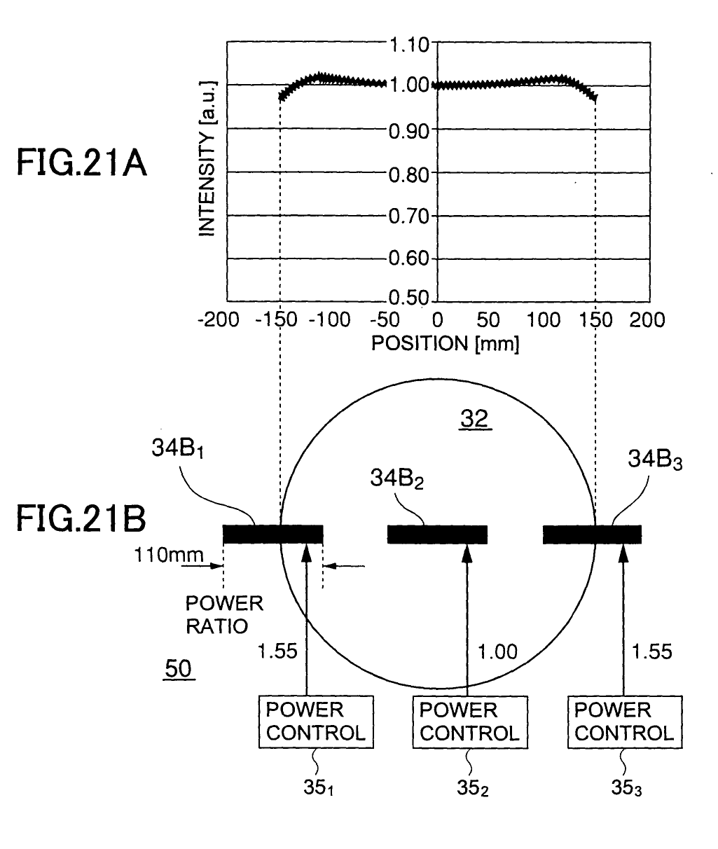

Next, a substrate processing apparatus 50 according to a fifth embodiment of the present invention will be described with reference to FIGS. 20A and 20B and FIGS. 21A and 21B, wherein the substrate processing apparatus 50 is an expansion of the substrate processing apparatus 30′ of the previous embodiment for handing large diameter substrate of the future.

Referring to FIGS. 20A and 20B, FIG. 20B shows the substrate processing apparatus 30′ of FIG. 16 in a plan view, while FIG. 20A shows the distribution of the ultraviolet radiation intensity on the substrate 32 for the case the substrate 32 has a diameter of 300 mm. In FIG. 20A, it should be noted that the illustrated radiation intensity distribution of FIG. 20A represents the one measured at the location right underneath the ultraviolet source for the case the substrate 32 of 300 mm diameter is irradiated with the linear ultraviolet source 34B having a length of 330 mm from the height of 100 mm above the substrate. In FIGS. 20A and 20B, those parts corresponding to the parts described previously are designated by the same reference numerals and the description thereof will be omitted.

Referring to FIG. 20A, it can be seen that the ultraviolet radiation intensity is decreased by as much as 30% at the edge part of the substrate 32 in the event the substrate processing apparatus 30′ of FIG. 16 is used straightforward for the processing of the large-diameter substrate having a diameter of 300 mm or more. In order to improve the uniformity of distribution of the ultraviolet radiation intensity for the processing of such large-diameter substrates, it is of course possible to increase the length of the linear optical source 34B. However, such an approach invites increase of size of the substrate processing apparatus and is not acceptable.

FIGS. 21A and 21b show the construction of a substrate processing apparatus 50 according to the present embodiment wherein the foregoing problems are eliminated. In FIGS. 21A and 21B, those parts corresponding to the parts described previously are designated by the same reference numerals and the description thereof will be omitted. Similarly to FIGS. 20A and 20B, FIG. 21B shows the substrate processing apparatus 50 in a plan view while FIG. 21A shows the distribution of the ultraviolet radiation intensity on the substrate 32.

Referring to FIG. 21B, the present embodiment constructs the linear ultraviolet source 34B by arranging a plurality of linear optical sources 34B₁, 34B₂ and 34B₃ on a single line, and each of the optical sources are driven by a corresponding driving apparatus 35₁, 35₂ or 35₃.

FIG. 21A shows the optical intensity distribution in a region of the substrate 32 right underneath the ultraviolet source for the case the optical output of the ultraviolet sources 34B₁, 34B₂ and 34B₃ are controlled to the ratio of 1:1.5:1.

As can be seen in FIG. 21A, the variation of the ultraviolet radiation intensity, having the value reaching 30% in the case of FIG. 20A, is now reduced to about 3.5%. Thus, by constructing the linear ultraviolet source 34B used in the substrate processing apparatus 30 of the first embodiment explained with reference to FIG. 3 or the substrate processing apparatus 30′ explained with reference to FIG. 16, with a plurality of linear ultraviolet radiation source elements, and by driving the foregoing plurality of ultraviolet radiation source elements individually, and further by moving the plurality of ultraviolet radiation source elements collectively so as to scan over the surface of the substrate 32, it becomes possible to form an oxide film of extremely uniform thickness on the substrate 32.

Further, by applying the optimum seeking procedure similar to one shown in the flowchart of FIG. 9 to the foregoing output ratio of the ultraviolet source elements for seeking for the optimum drive condition corresponding to the optimum film thickness distribution, further improvement is achieved for the uniformity of film thickness by correcting the factors pertinent to the processing apparatus. In the present embodiment, therefore, the ratio of the driving power is changed-in the ultraviolet sources 34B1-34B3 in the present embodiment in the step 1 of FIG. 8 in place of specifying the scanning region and the result of film formation is evaluated in the step 3. Further, in the step 4, an optimum ratio of the driving power is selected in place of selecting the optimum scanning region.

[Sixth Embodiment]

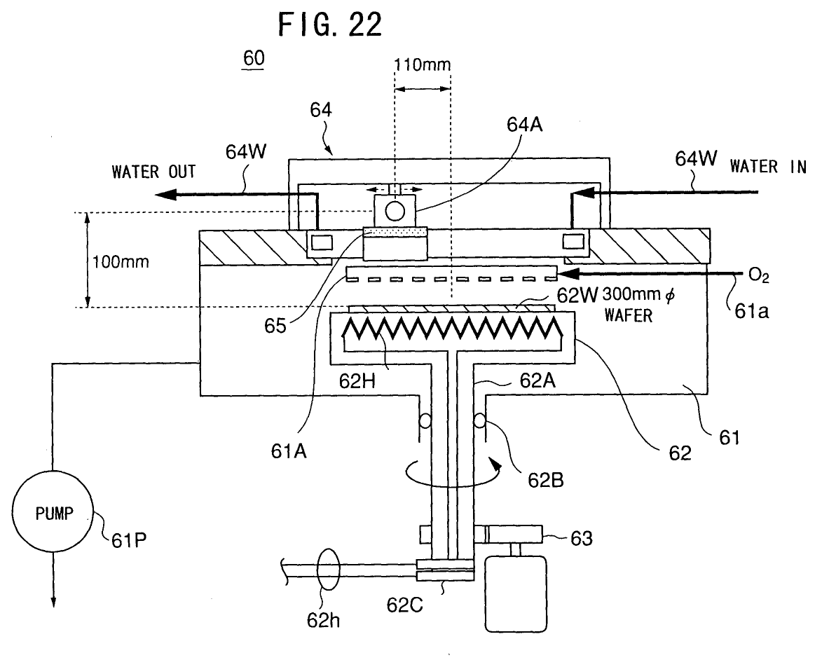

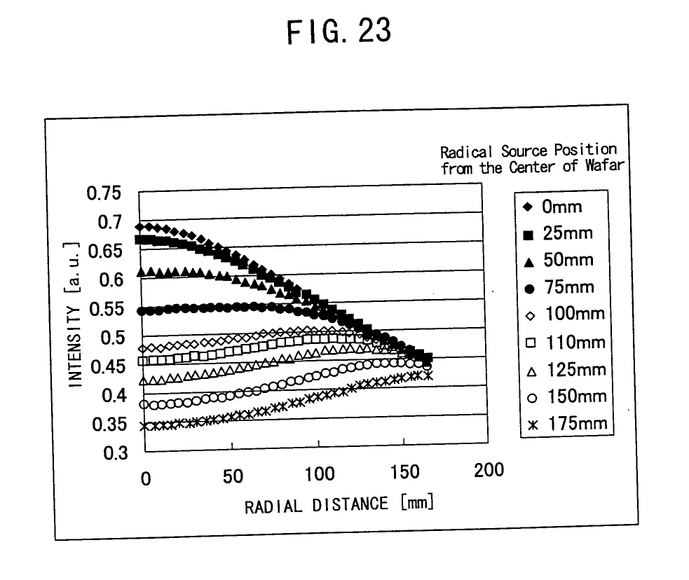

Next, the construction of a substrate processing apparatus 60 according to a sixth embodiment of the present invention will be explained with reference to FIG. 22. It should be noted that the substrate processing apparatus 60 is tuned up for further device miniaturization expected in the further and uses a rotating mechanism of the substrate in combination with one or more linear ultraviolet sources.

FIG. 22 shows the construction of the substrate processing apparatus 60 according to an embodiment of the present invention, wherein those parts corresponding to the parts described previously are designated by the same reference numerals and the description thereof will be omitted.

Referring to FIG. 22, the substrate processing apparatus 60 includes a processing vessel 61 similar to the processing vessel 31 of the substrate processing apparatus 30 of the first embodiment, and a stage 62 holding a substrate 62W of 300 mm diameter is provided inside the processing vessel 61, wherein the stage 62 is rotated by a rotation driving part 63. Further, a single optical source unit 64 including a linear ultraviolet source 64A having a length of 330 mm is provided above the processing vessel 61, and the ultraviolet optical source 64A irradiates the substrate on the stage 62 through the ultraviolet-transparent window 65. The processing vessel 61 is evacuated by a vacuum pump 61P, and there is provided a quartz shower nozzle 61A in the processing vessel 61 so as to face the substrate, wherein the shower nozzle 61A is supplied with O₂ via a line 61a. Further, the optical source unit 64 is provided with a cooling water passage and cooling water circulating through a line 64W cools the optical source unit 64. Further, the stage 62 is provided with a heat source 62H such as a heater for controlling the temperature of the substrate 62W.

In the construction of FIG. 22, the stage 62 is-connected to a rotary shaft 62A, wherein the rotary shaft 62A is provided with a vacuum seal 62B of a resin O-ring or more preferably of a magnetic fluid seal, such that the interior of the processing vessel 61 is sealed. Further, the ultraviolet source 64A is provided with offset from the center of the substrate as represented in FIG. 22. The heat source 62H in the stage 62 is driven by a driving line 62h, wherein the driving line 62h extends to the outside of the processing vessel 61 via a contact 62C.

FIG. 23 shows the radial distribution of the ultraviolet intensity on the substrate 62W for the case the substrate 62W is rotated in the substrate processing apparatus 60 of FIG. 22 while changing the relative relationship between the ultraviolet source 64A and the substrate 62W variously. In FIG. 23, it should be noted that the horizontal axis represents the radial distance of the substrate 62W while the vertical axis represents the average ultraviolet radiation intensity at each point. In FIG. 23, it should be noted that the distance in the height direction (work distance) between the substrate 62W and the optical source 64A is set to 100 mm.

Referring to FIG. 23, the radiation intensity is maximum at the substrate center (0 mm on the horizontal axis) and decreases toward the marginal part of the substrate when the optical source 64A is located near the center (such as 0 mm) of the substrate 62W, as can be seen from the plot of the corresponding offset. In the case the ultraviolet source 64A is displaced from the center of the substrate 62W with a large distance such as 150 mm, on the other hand, there appears a tendency in which the distribution of the radiation intensity is small at the center of the substrate and increases toward the substrate edge. Particularly, in the event the ultraviolet source 64A is disposed at the radial distance of 110 mm from the center of the substrate 62A, it can be seen that the variation of intensity of the ultraviolet radiation becomes small and falls within the range of about 10%.

Thus, in the substrate processing apparatus 60 of FIG. 22, it becomes possible to form an oxide film of extremely uniform thickness, by setting the ultraviolet source 64A at the location offset by the distance of 110 mm from the center of the substrate 62W in the radial direction as represented in FIG. 22 and by setting the height of the ultraviolet source 64A to 100 mm, and by conducting the ultraviolet-activated oxidation processing while rotating the substrate 62W and the ultraviolet source 64A relatively with each other.

Further, it is also possible to modify the thickness distribution of the oxide film formed on the substrate 64A by displacing the ultraviolet source 64A from the optimum location within a limited range such as the range of 75-125 mm, as represented by arrows in FIG. 22. Further, it is also possible to achieve higher degree of uniformity for the oxide film by compensating for any factors causing non-uniform film thickness distribution pertinent to the substrate processing apparatus 60. In such a case, the flowchart explained with reference to FIG. 9 seeking for the optimum film thickness distribution is applied for obtaining the optimum offset for the ultraviolet source 64A. Further, in the substrate processing apparatus 60 of the present embodiment, it becomes possible to reduce the overall size of the apparatus in view of the limited moving range of the ultraviolet source 64A as compared with the substrate processing apparatus 30 or 30′ of the first embodiment.

[Seventh Embodiment]

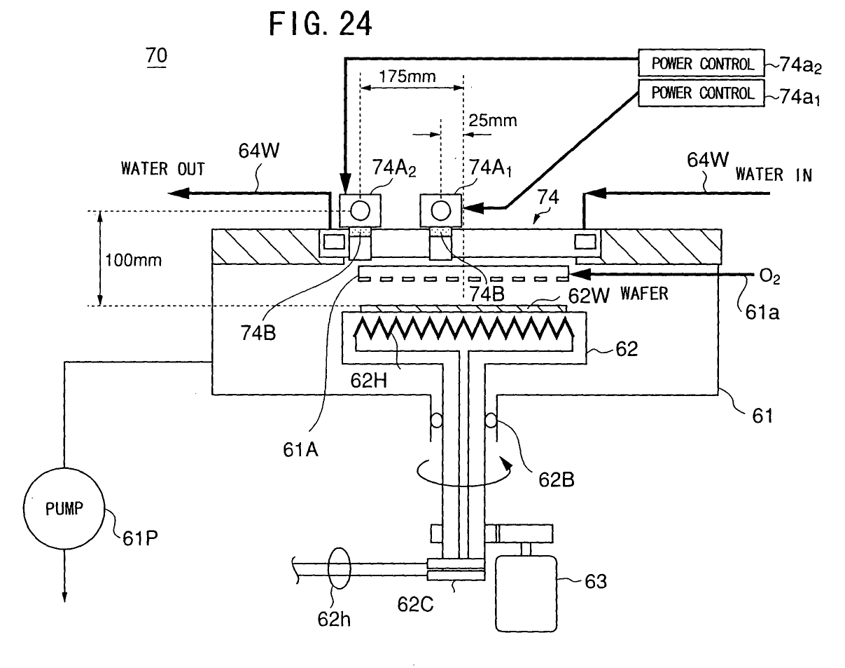

FIG. 24 is a diagram showing the construction of a substrate processing apparatus 70 according to a seventh embodiment of the present invention. In FIG. 24, those parts corresponding to the parts described previously are designated by the same reference numerals and the description thereof will be omitted.

Referring to FIG. 24, the present embodiment has a construction similar to that of the substrate processing apparatus 60 of the previous embodiment, except that there are provided a plurality of fixed ultraviolet sources 74A₁ and 74A₂ in place of the optical source unit 64 using a single movable ultraviolet source 64A, such that the fixed ultraviolet sources 74A₁ and 74A₂ are provided with offset from the center of the substrate 62W. Further, the fixed ultraviolet sources 74A₁ and 74A₂ are driven by respective driving apparatuses 74a₁ and 74a₂. In the illustrated example, the ultraviolet source 74A₁ is provided at a location offset by 25 mm from the center of the substrate 62W in the radially outward direction, while the ultraviolet source 74A₂ is provided at a location offset by 175 mm from the center of the substrate 62W in the radially outward direction. Further, the optical source unit 74 is provided with a window 74B transparent to ultraviolet radiation in correspondence to the foregoing ultraviolet sources 74A₁ and 74A₂.

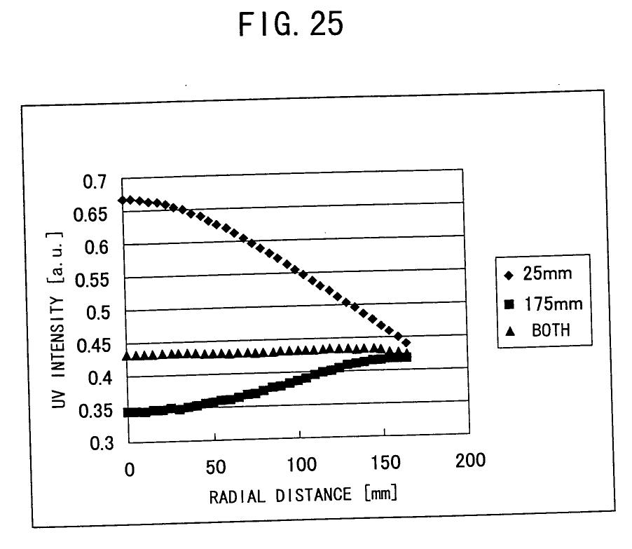

FIG. 25 shows the intensity distribution of the ultraviolet radiation on the substrate 62W produced solely by the ultraviolet source 74A₁ and the intensity distribution of the ultraviolet radiation produced on the substrate 62W solely by the ultraviolet source 74A₂, together with the intensity distribution of the ultraviolet radiation for the case both of the ultraviolet radiation sources 74A₁ and 74A₂ are activated. In the experiment of FIG. 25, it should be noted that the ultraviolet source 74A₁ is provided with an offset of 25 mm from the center of the substrate 62W in the radially outward direction, while the ultraviolet source 74A₂ is provided with an offset of 175 mm from the center of the substrate 62W in the radially outward direction. In the example of FIG. 25, the ultraviolet radiation source 74A₁ is driven by the driving apparatus 74a₁ with a power of 73%, while the ultraviolet radiation source 74A₂ is driven by the corresponding driving apparatus 74a₂ with a power of 27%.

As can be seen from FIG. 25, each of the ultraviolet sources 74A₁ and 74A₂ forms a monotonously changing intensity distribution for the ultraviolet radiation in the case the ultraviolet source is driven alone, while it will be also noted that the sense of the change is opposite. Thus, by optimizing the driving power of each of the ultraviolet sources 74A₁ and 74A₂, it becomes possible to realize a uniform distribution for the ultraviolet radiation on the substrate 62W. In the example of FIG. 25, the variation of the ultraviolet radiation intensity is suppressed to the order of 2%. Such an optical driving power can be obtained by using the optimum seeking procedure explained already with reference to FIG. 9. Thereby, the driving power of the driving apparatuses 74a₁ and 74a₂ are changed in the step 1 and the result of film formation is evaluated in the step 3. Further, the optimum value is determined in the step 4.

[Eighth Embodiment]

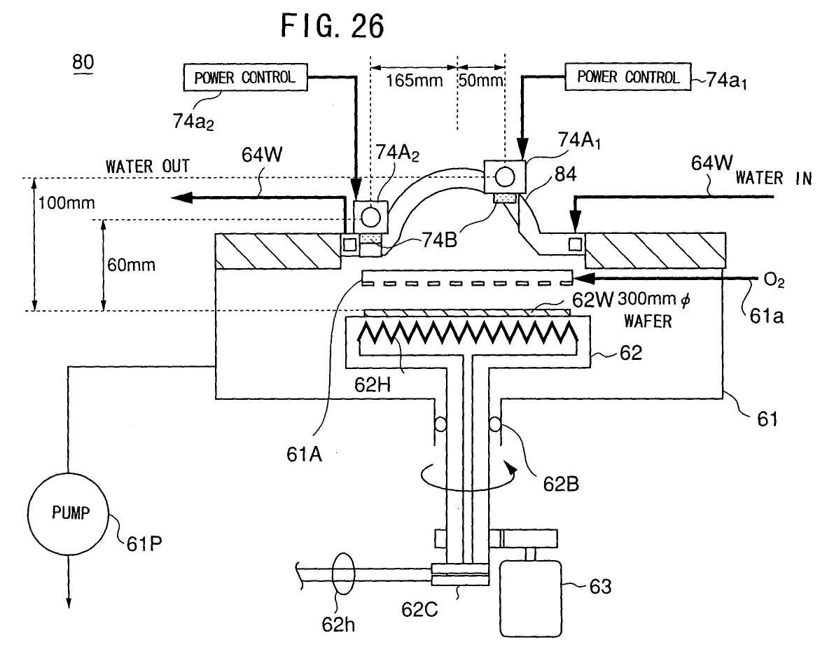

FIG. 26 shows the construction of a substrate processing apparatus 80 according to an eighth embodiment of the present invention, wherein those parts of FIG. 26 corresponding to the parts explained previously are designated by the same reference numerals and the description thereof will be omitted.

Referring to FIG. 26, the substrate processing apparatus 80 has a construction similar to that of the substrate processing apparatus 70 of the previous embodiment, except that an optical source unit 84 formed of a bulging aluminum dome is provided in place of the optical source unit 74 of the substrate processing apparatus 70. On the optical source unit 84, it will be noted that the ultraviolet sources 74A₁ and 74A₂ are provided with different heights or different distances as measured from the surface of the substrate 62W.

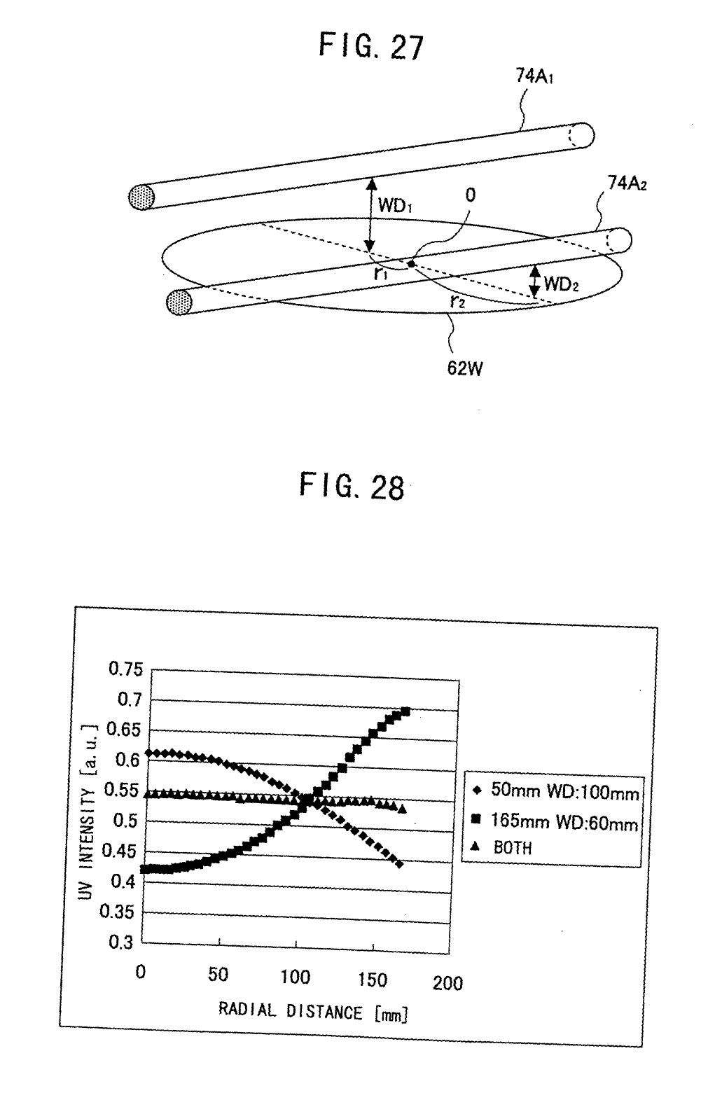

FIG. 27 shows the relationship between substrate 62W and the ultraviolet source 74A₁ or 74A₂ in the substrate processing apparatus 80 of FIG. 26.

Referring to FIG. 27, the ultraviolet source 74A₁ is provided with a first work distance WD₁ at a location offset by a distance r1 from the center O of the substrate 62W in the radial direction thereof, while the ultraviolet source 74A₂ is provided with a second, smaller work distance WD₂ at a location offset by a larger distance r2 from the center O of the substrate 62W in the radial direction thereof. Similarly to the substrate processing apparatus 70 explained before, the ultraviolet source 74A₁ is driven by the driving apparatus 74a₁ and the ultraviolet source 742 is driven by the driving apparatus 74a₂, independently from each other.

FIG. 28 shows the intensity distribution of the ultraviolet radiation on the-substrate 62W produced solely by the ultraviolet source 74A₁ and the intensity distribution of the ultraviolet radiation produced on the substrate 62W solely by the ultraviolet source 74A₂, together with the intensity distribution of the ultraviolet radiation for the case both of the ultraviolet radiation sources 74A₁ and 74A₂ are activated, for the case the distances r1 and r2 are set to 50 mm and 165 mm respectively and the work distances WD1 and WD2 are set to 100 mm and 60 mm respectively in the substrate processing apparatus 80 of FIG. 26. In FIG. 28, it should be noted that the ultraviolet source 74A₁ is driven with the power of 64% while the ultraviolet source 74A₂ is driven with the power of 36%.

Referring to FIG. 28, it will be noted that the distribution of the ultraviolet optical radiation intensity changes monotonously in opposite directions between the ultraviolet source 74A₁ and the ultraviolet source 74A₂, and thus, it is possible to suppress the variation of the ultraviolet intensity to 2% or less, by superimposing the ultraviolet intensity distribution caused by the ultraviolet source 74A₁ and the ultraviolet intensity distribution caused by the ultraviolet source 74A₂.

In the present embodiment, too, it is possible to obtain the optimum driving power of the ultraviolet sources 74A₂ by the optimum seeking procedure similar to that of FIG. 9.

[Ninth Embodiment]

Next, description will be made on the substrate processing apparatus using a remote plasma source according to a ninth embodiment of the present invention.

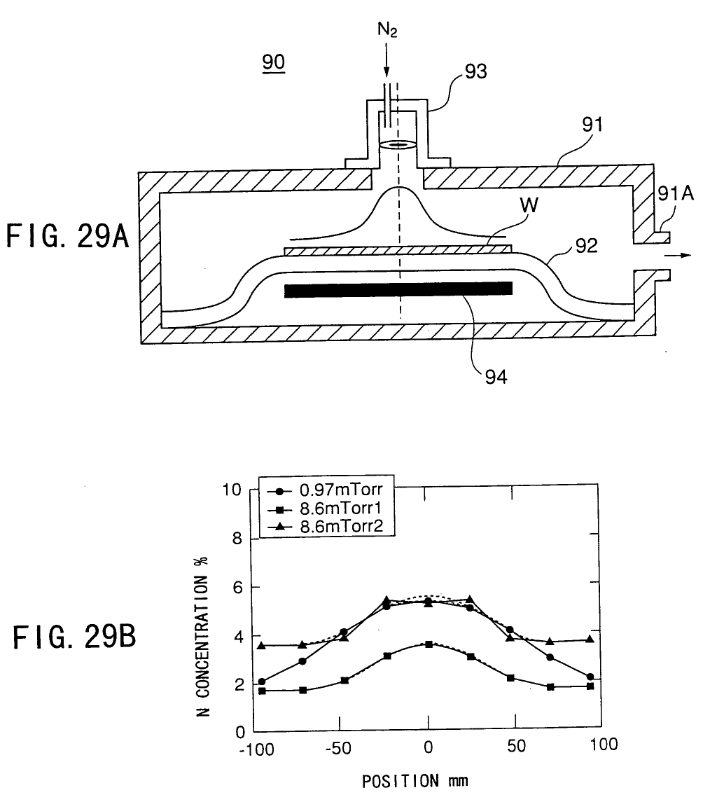

FIG. 29A shows the construction of an ordinary remote plasma substrate processing apparatus 90, wherein it should be noted that the substrate processing apparatus 90 is the one used for conducting a nitridation processing for forming a nitride film on the surface of an SiO₂ film formed on a Si substrate as a result of nitridation reaction.

Referring to FIG. 29A, the substrate 90 includes a processing vessel 91 evacuated from an evacuation port 91A, wherein the processing vessel 91 is provided with a quartz stage 92 for holding a substrate W, and the processing vessel 91 carries thereon a remote plasma source 93 in the state that the remote plasma source 93 faces the substrate W, wherein the remote plasma source 93 is supplied with a N₂ gas and forms active N₂ radicals by activating the same with plasma. Further, a heater 94 is formed underneath the quartz stage 92 in correspondence to the substrate W. FIG. 29A further shows the distribution of the N2 radicals formed by the remote plasma source 93. Naturally, the concentration of the N₂ radicals becomes maximum at the part right underneath the remote plasma source 93. In the case the remote plasma source 93 is provided at the center of the substrate W, the concentration of the N₂ radicals becomes maximum at the center of the substrate W.

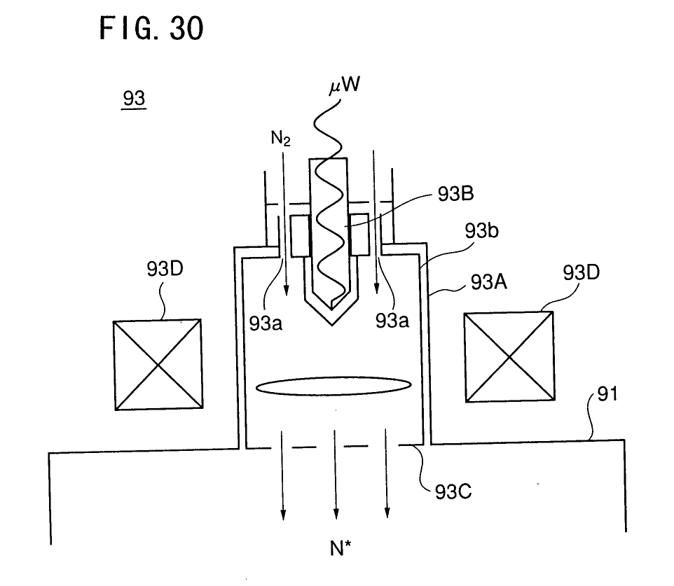

FIG. 30 shows the construction of the remote plasma source 93 in detail.

Referring to FIG. 30, it will be noted that the remote plasma source 93 includes a main body 93A having a first end mounted on the processing vessel 91, wherein the main body 93A further includes a quartz liner 93b, and an inlet 93a of a plasma gas such as N₂, Ar or the like, is formed at the other end of the maim body 93A. Further, the remote plasma source 93 includes an antenna 93B at the aforesaid the other end of the main body 93A and the a quartz diffusion plate 93 formed at the foregoing first end of the main body 93, wherein the antenna 93B is supplied with a microwave while the quartz diffusion plate 93C supplies the active radicals formed in the remote plasma source 93 to the processing vessel 91 via a number of openings. Further, there is provided a magnet 93D outside the main body 93A between the foregoing first end and the foregoing the other end. In such a remote plasma source 93, therefore, plasma is formed in the main body 93A in correspondence to the location of the magnet 93D by supplying an N₂ gas or Ar gas into the main body 93A via the gas inlet 93a and by supplying a microwave to the antenna 93B. The plasma thus formed cause activation of the N₂ gas, and the nitrogen radicals N* formed as a result are introduced into the processing vessel 91 through the diffusion plate 93C.

FIG. 29B shows the concentration of N on the substrate surface for the case an SiON film is formed on an Si substrate W formed with the SiO₂ film by the substrate processing apparatus 90 of FIG. 29A under various conditions, wherein it should be noted that the N distribution in FIG. 29B represents the profile as measured in the radial direction with regard to the origin chosen at the center of the substrate W.

Referring to FIG. 29B, it can be seen that there is formed a non-uniform distribution of N on the substrate W and that the N concentration becomes maximum at the center of the substrate W. Further, it will be noted that the N distribution is generally symmetric with regard to the center of the substrate W. This means that it is not possible to achieve a uniform distribution of N even when the substrate is rotated, in view of the fact that there is formed such a symmetric distribution of N.

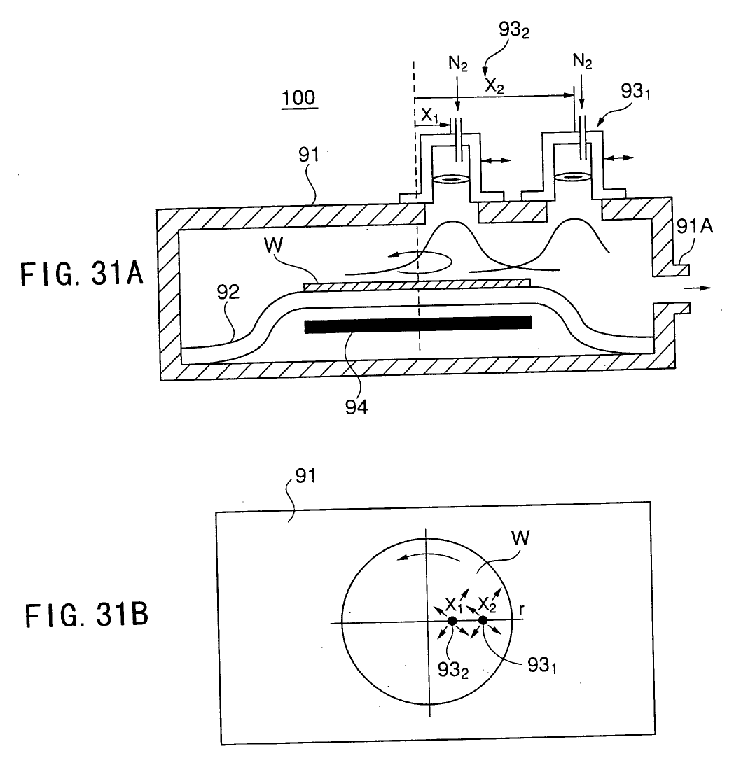

FIGS. 31A and B show the construction of a substrate processing apparatus 100 according a ninth embodiment of the present invention, wherein it should be noted that FIG. 31A shows the cross-sectional view while FIG. 31B shows a plan view. In FIGS. 31A and 31B, those parts corresponding to the parts described previously are designated by the same reference numerals and the description thereof will be omitted.

Referring to FIGS. 31A and 31B, it will be noted that there are provided a plurality of remote plasma sources 93₁ and 93₂ at respective locations (x₁, 0) and (x₂, 0) with offset from the center of the substrate W, and as a result, there is formed a radical distribution on the substrate W such that the distributions of the radicals originating from these remote plasma sources are superimposed. Thus, by rotating the substrate W as represented in FIGS. 31A and 31B, the radical distribution on the substrate W is averaged.

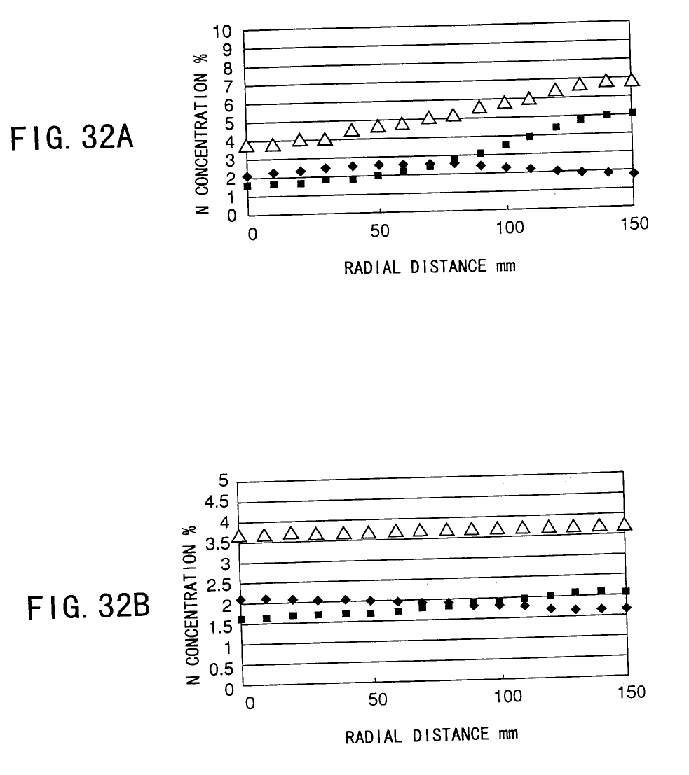

FIG. 32A shows the distribution of N on the substrate W after the nitridation processing for the case in which the substrate W is fixed and not rotated. In FIG. 32A, it should be noted that a Si substrate formed with an SiO₂ film on the surface thereof is used for the substrate W. On the other hand, FIG. 32B shows the distribution of N on the substrate surface for the case the nitridation processing has been conducted while rotating the substrate W about a center thereof. In FIGS. 32A and 32B, the points represented by ▪, ♦ and Δ correspond respectively to the cases of forming an SiON film in which only the remote plasma source 93₁ is used, only the remote plasma source 93₂ is used, and both of the remote plasma sources 93₁ and 93₂ are used.

Referring to FIG. 32A, it will be noted that a N distribution changing gently in the radial direction of the substrate is obtained for the case the substrate W is not rotated, while in the case the substrate W is rotated, an extremely uniform N concentration is obtained.

In the substrate processing apparatus 100 of FIGS. 31A and 31B, it should be noted that the foregoing remote plasma sources 93₁ and 93₂ are provided on the processing vessel 91 movably as represented by arrows in FIGS. 31A and 31B so as to enable uniform N distribution represented in FIG. 32B for the case the substrate is rotated, and that the remote plasma sources 93₁ and 93₂ are fixed at the optimum locations providing the uniform N distribution represented in FIG. 32B.

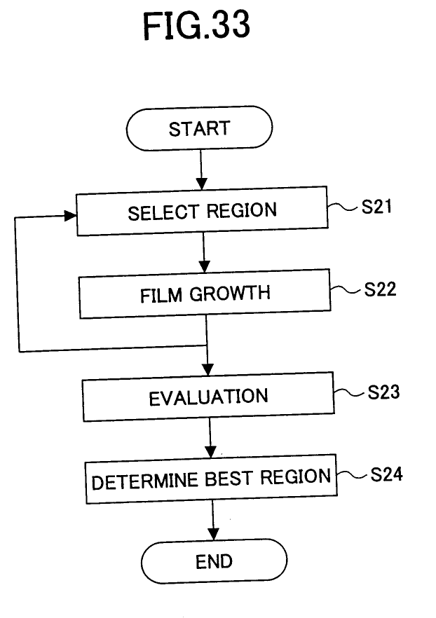

FIG. 33 shows the flowchart for seeking for such optimum locations.

Referring to FIG. 33, an arbitrary location on the substrate is specified for the remote plasma sources 93₁ and 93₂ in the first step 21, and the remote plasma sources 93₁ and 93₂ are fixed on the processing vessel 91 at the foregoing specified locations. Next, in the step 22, the substrate W is introduced into the substrate processing apparatus 100 and the formation of an SiON film is conducted by driving the remote plasma sources 93₁ and 93₂ while rotating the substrate W. Further, by repeating the steps 21 and 22, new SION films are formed on new substrates W while displacing the location of the remote plasma sources 93₁ and 93₂ each time.

The N distribution of the SiON film thus obtained is evaluated for each of the experiments in the step 23, and the optimum location for the remote plasma sources 93₁ and 93₂ that minimizes the variation of the concentration is determined in the step 24.

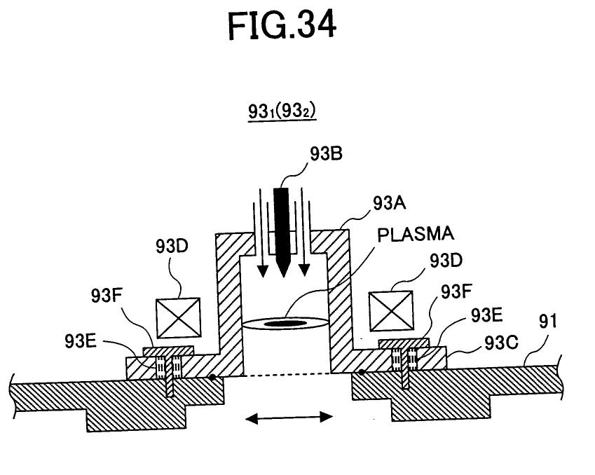

FIG. 34 shows the mechanism of mounting the remote plasma sources 931 and 932 on the processing vessel 91 in a movable manner, wherein those parts of FIG. 34 explained previously are designated by the same reference numerals and the description thereof will be omitted.

Referring to FIG. 34, it will be noted that the main body 93A is provided with a mounting flange 93c for engagement with an outer wall of the processing vessel 91, and the main body 91A is fixed on the processing vessel 91 by screwing the mounting flange 93c at screw holes 93E by using screws 93F. In such a construction of FIG. 34, it should be noted that the screw holes 93E are formed larger than the screws 93F, and thus, the main body 93A is movable in the direction of the arrows when the screws 93F are loosened.

In the construction of FIG. 34, it is also possible to eliminate the screws 93F and the screw holes 93E and form the flange 93c so as to slide with respect to the outer wall of the processing vessel 91.

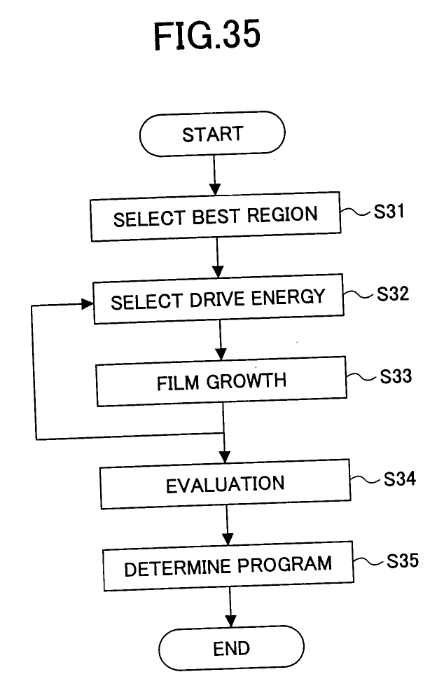

Further, in the present embodiment, the driving power is optimized as represented in FIG. 35 after the optimization for the location of the remote plasma sources 93₁ and 93₂.

Referring to FIG. 35, the optimum location searched by the procedure of FIG. 33 is specified for the remote plasma sources 93₁ and 93₂ in the first step 31, and the driving energy is specified in the step 32 for the remote plasma sources 93₁ and 93₂. Further, in the step 33, the substrate W is introduced into the substrate processing apparatus and the remote plasma sources 93₁ and 93₂ are driven on the substrate W at the respective, specified locations with the driving energy specified in the step 32. As a result, there is formed an SiON film. Further, by repeating the steps 21 and 22, new SiON films are formed on new substrates W each time the location of the remote plasma sources 93₁ and 93₂ are displaced.

Further, in the step 34, the distribution of nitrogen in the SiON film is evaluated for each of the experiments, and the optimum driving energy that minimizes the variation of the concentration is determined for the remote plasma sources 93₁ and 93₂. Further, in the step 35, a control program for controlling the remote plasma sources 931 and 932 of the substrate processing apparatus 100 is determined such that the film formation is achieved under such optimum driving energy.

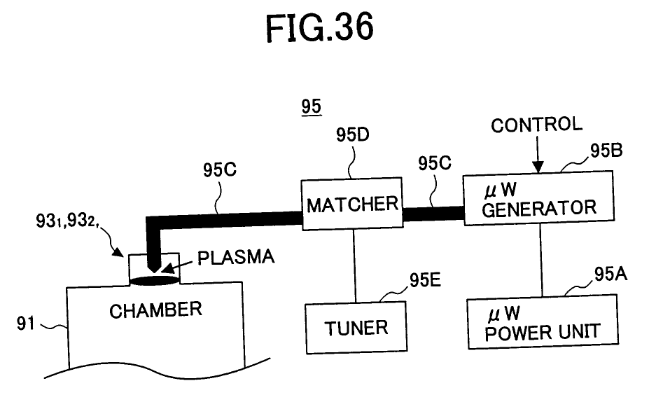

FIG. 36 shows the construction of a driving circuit 95 of the remote plasma sources 93₁ and 93₂.

Referring to FIG. 36, the driving circuit 95 includes a microwave generator 95B driven by a microwave power supply 95A, and the microwave produced by the microwave generator 95B typically with a frequency of 2.45 GHz is supplied to an impedance matcher 95D via a waveguide 95C. The microwave is then fed to the foregoing antenna 93B. Further, it should be noted that the driving circuit 95 is provided with a tuning circuit 95E for matching the impedance of the impedance matcher 95D with the impedance of the antenna 93B.

According to the driving circuit 95 of such a construction, it is possible to optimize the driving energy of the remote plasma sources 93₁ and 93₂ by controlling the microwave generator 95B in the step 32 of FIG. 35.

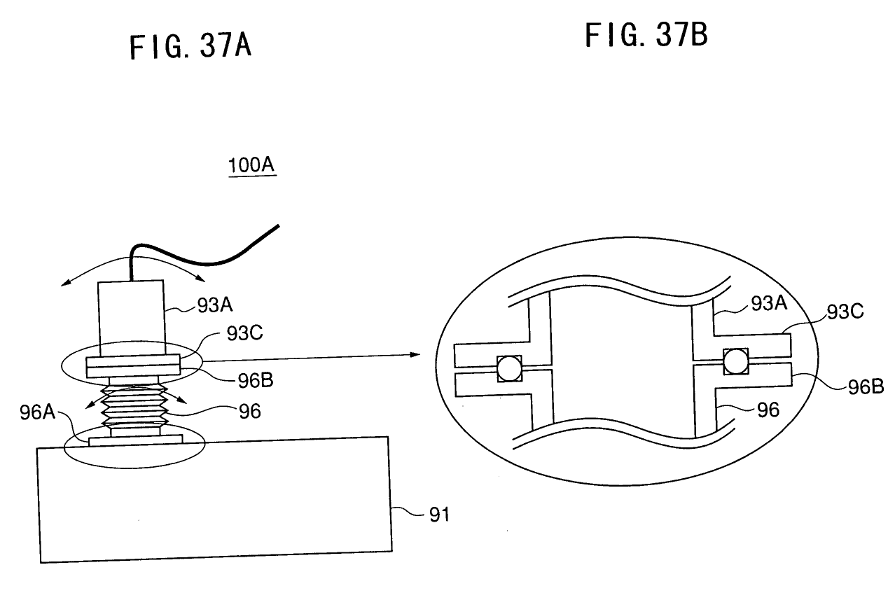

FIGS. 37A and 37B show the construction of a substrate processing apparatus 100A according to a modification of the present embodiment, wherein FIG. 37B is an enlarged cross-sectional diagram showing a part of FIG. 37A in an enlarged scale.

Referring to FIGS. 37A and 37B, it should be noted that a bellows 96 having flange parts 96A and 96B are mounted on the substrate processing vessel 91 by the foregoing flange part 96A, and the main body 93A of the remote plasma source 93₁ or 93₂ is mounted on the bellows 96 by engaging the mounting flange 93c with the flange 96B.

In the substrate processing apparatus 100A of such a construction, it is possible to change the angle of the remote plasma source with respect to the substrate W by deforming the bellows 96, and thus, it is also possible to determine an optimum angle for the remote plasma sources 931 and 932 in the step of FIG. 33 explained before, in place of determining the optimum locations.

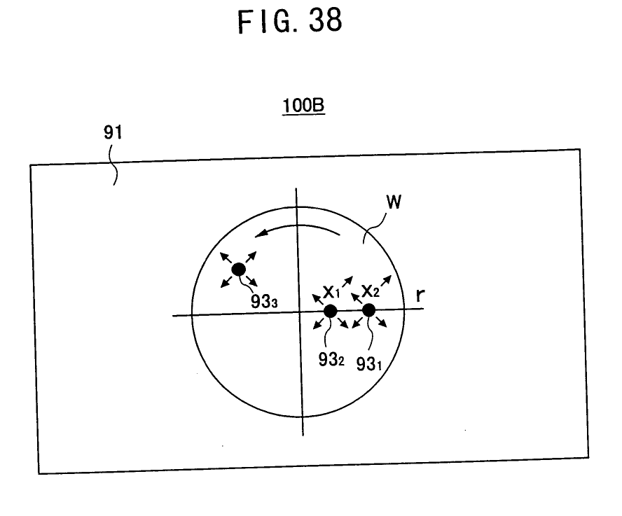

FIG. 38 shows the construction of a substrate processing apparatus 100B according to a further modification of the present embodiment, wherein those parts corresponding to the parts described previously are designated by the same reference numerals and the description thereof will be omitted.

Referring to FIG. 38, the substrate processing apparatus 100B includes a third remote plasma source 933 movably as represented by arrows in addition to the foregoing remote plasma sources 93₁ and 93₂, wherein it should be noted that the present invention is effective also for such a substrate processing apparatus having three or more remote plasma sources. Further, the present invention is effective also for the substrate processing apparatus having a single remote plasma source.

Further, the present embodiment is effective not only for the formation of an SiON film conducted by nitridation of an Si substrate formed with an SiO₂ film, but also for the formation of an SiO₂ film by way of oxidation reaction or formation of an SiN film, or formation of a high-K dielectric film such as a Ta₂O₅ film, a ZrO₂ film, a HfO₂ film, a ZrSiO₄ film, a HfSiO₄ film, and the like, which is conducted by a CVD process.

[Tenth Embodiment]

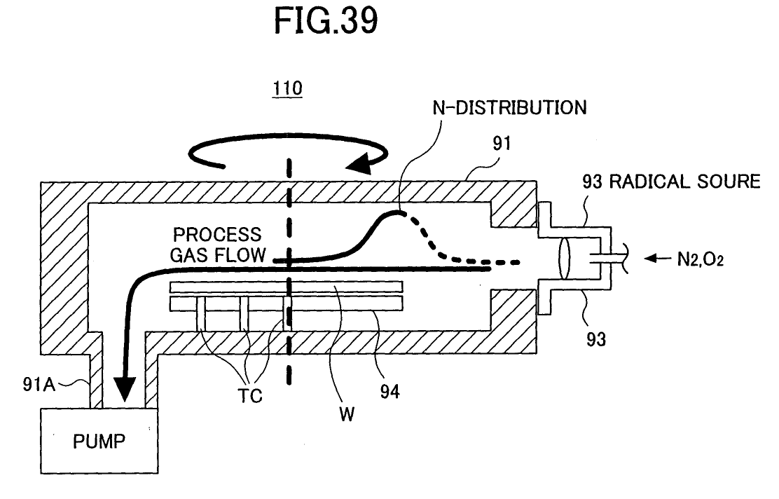

FIG. 39 shows the construction of a substrate processing apparatus 110 according to a tenth embodiment of the present invention, wherein those parts corresponding to the parts described previously are designated by the same reference numerals and the description thereof will be omitted.

Referring to FIG. 39, the remote plasma radical source 93 is provided on a sidewall of the processing vessel 91, and the radicals introduced from the remote plasma radical source 93 are caused to flow along the surface of the substrate W in the processing vessel 91. Further, the radicals thus traveled are discharged from an evacuation port 91A provided at an end of the processing vessel opposing the remote plasma radical source 93. Thus, in the substrate processing apparatus 110, there is formed a radical flow flowing along the surface of the substrate W.

In the processing vessel 91, it should be noted that the substrate W is held rotatably and a plurality of thermocouples TC are provided at different radial locations underneath the substrate W for the measurement of temperature distribution. In the present embodiment, the substrate W is rotated by a rotating mechanism not illustrated.

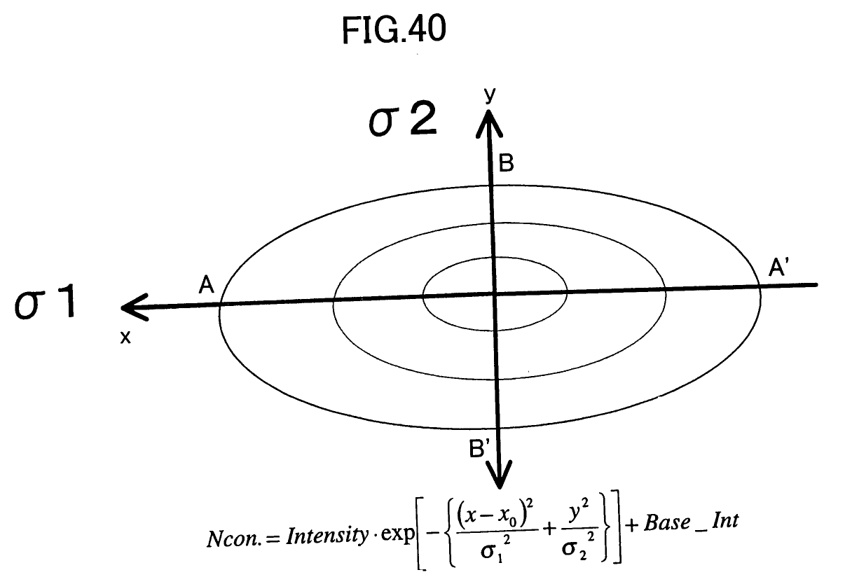

FIG. 40 shows the representation form of the radical distribution formed inside the processing vessel 91 of the substrate processing apparatus 110 of FIG. 39.

Referring to FIG. 40, the radicals released from the radical source 93 are believed to form an ordinary, Gaussian distribution in the case there is no radical flow inside the processing vessel 91. In the present embodiment, on the other hand, there is formed a radical flow inside the processing vessel 91 such that the radicals are caused to flow on the substrate W from the plasma radical source 93 to the evacuation port 91 as explained before. Thus, in order to investigate the effect of such a radical flow on the distribution of the radicals, the present invention employs the representation:

$$Ncon . = Intensity * exp [ - \{ \frac{{( x - {x}_{0} )}^{2}}{{σ}_{1}^{2}} + \frac{{y}^{2}}{{σ}_{2}^{2}} \} ] + Base\_Int . \qquad ( 1 )$$

for representing the radical distribution, wherein it should be noted that the representation is an expansion of the ordinary Gaussian distribution by employing the coordinate axis x set in the direction parallel to the flow direction and the coordinate axis y set in the direction perpendicular to the x-axis. In Eq.(1), it should be noted that σ1 and σ2 are characteristic parameters or concentration distribution parameters for the case the actual concentration parameters are fit by using Eq.(1). Thereby, σ1 represents the degree of expansion of the radical distribution in the direction of the x-axis, while σ2 represents the degree of expansion of the radical distribution in the direction of the y-axis. By using the concentration distribution parameters σ1 and σ2, elliptical contours represented in FIG. 40 are obtained for the radical distribution for the case of viewing the radical distribution from the direction perpendicular to the substrate W. In Eq.(1), it should be noted that the term “Base_Int” represents the base concentration value of the radicals, and the maximum value of the radical concentration is given by the sum of Base_Int and the concentration represented by the Gaussian. The radical distribution thus represented coincides with the distribution after the nitrogen radical processing has been conducted by using the substrate processing apparatus 110.

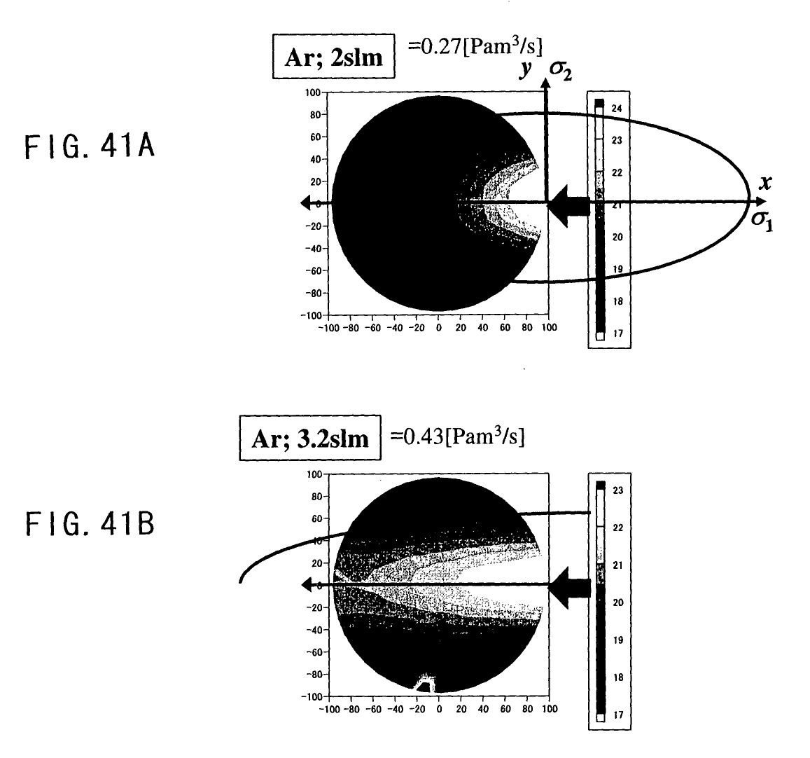

FIGS. 41A and 41B show the value of the concentration distribution parameters σ1 and σ2 for the distribution of the nitrogen radicals respectively for the case the flow rate of the Ar plasma gas supplied to the plasma radical source 93 is set to 2SLM (=0.27 Pa.m³/sec) and 3.2SLM (=0.43 Pa.m³/sec), wherein it should be noted that there is formed an SiO2 film on the surface of the substrate W in FIGS. 41A and 41B and a part of the SiO₂ film is converted to an oxynitride film by introducing nitrogen as a result of the nitrogen radical processing. FIGS. 41A and 41B show the film thickness distribution of the SiO₂ film or the oxynitride film thus formed on the substrate W, wherein it should be noted that the film thickness shown in FIGS. 41A and 41B is an apparent thickness obtained by ellipsometry. In the case of using ellipsometry, it should be noted that there is caused a change of refractive index in the part where nitrogen is incorporated, and as a result, an apparently larger film thickness is tend to be observed.

Referring to FIG. 41A, it will be noted that the nitrogen radicals reach the central part of the substrate W in the event the Ar gas flow rate is set to 2SLM. Thus, the parameter σ1 characterizing the nitrogen radical distribution realized in such a state has a value of as large as 200 mm, while it is noted that the parameter σ2 takes a value of about 80 mm. On the other hand, it should be noted that there exist no radicals in this case that reach the opposite side of the substrate across the central part of the substrate W. This means that the radicals are annihilated in such an opposite region as a result of recombination, or the like.

In the case the Ar gas flow rate is set to 3.2SLM as represented in FIG. 41B, on the other hand, the radicals can flow across the surface of the substrate W before causing recombination because of the large velocity, and as a result, there appears a radical distribution characterized by the parameter σ1 much larger than the case of FIG. 41A. Even in this case, the parameter σ2 takes a value of about 80 μm, similarly to the case of FIG. 41A.

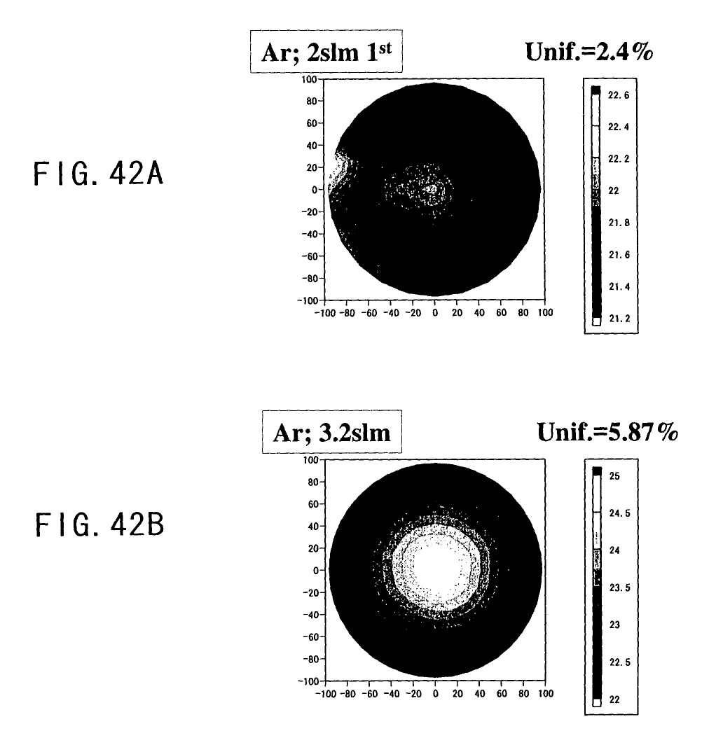

FIGS. 42A and 42B show the distribution of the nitrogen radicals on the surface of the substrate W for the case the substrate W is rotated in the cases of FIGS. 41A and 41B respectively, wherein the illustrated distribution is represented in terms of the film thickness distribution observed by ellipsometry.

Comparing FIGS. 42A and 42B, it can be seen that the nitrogen radical distribution of FIG. 41A is averaged as a result of rotation of the substrate W, and as a result, there is realized excellent uniformity in which the variation is improved up to 2.4%. In the case of the radical distribution of FIG. 41B, on the other hand, it can be seen that there is formed a large radical peak at the central part of the substrate as a result of rotation of the substrate W. This clearly reflects the situation of FIG. 41B showing the existence of radicals with substantial concentration at the central part of the substrate W. As a result, it can be seen that the variation has been increased to 5.9% in this case.

On the other hand, in the case the parameter σ2 takes a large value of about 300 μm, the distribution of the radicals on the surface of the substrate W is averaged by rotating the substrate W, and it becomes possible to suppress the variation to the value of 3% or less even in such a case in which the parameter σ1 takes a large value and the radicals reach the opposite region of the substrate W.

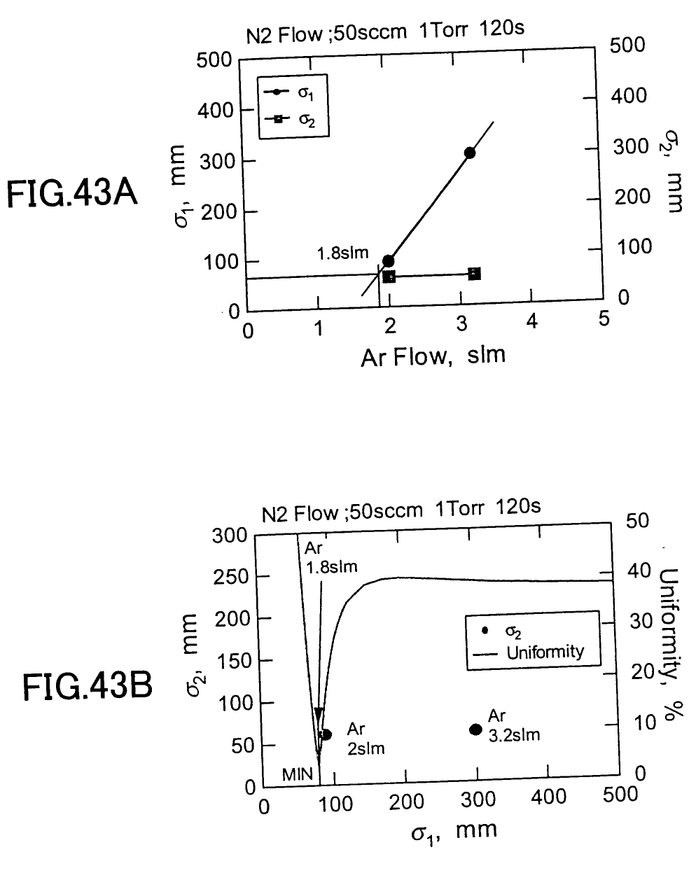

FIG. 43A shows the relationship between the flow rate of the Ar gas supplied to the plasma-radical source 93 and the foregoing concentration distribution parameters σ1 and σ2. In FIG. 43A, it should be noted that the flow rate of the N2 gas is set to 50 SCCM and the substrate processing is conducted under the pressure of 1 Torr (133 Pa) for 120 seconds.

As can be seen from FIG. 43A, the concentration distribution parameter σ2 does not change substantially when the Ar flow rate is changed, while the concentration distribution parameter σ1 changes significantly with such a change of the Ar flow rate.

FIG. 43B shows the relationship between the concentration distribution parameter σ1 and the uniformity of the nitrogen radical concentration for the case the substrate W is rotated, wherein it should be noted that the uniformity of the nitrogen radicals is represented by the rate of concentration variation similarly to the case of FIG. 42A,B. Thus, an ideal uniformity is realized in the case the rate of concentration variation is 0%. In FIG. 43B, it should be noted that the relationship between the parameters σ1 and σ2 is, although there are only two point, also represented. In FIG. 43B, too, the flow rate of the N₂ gas is set to 50 SCCM and the substrate processing is conducted under the pressure of 1 Torr (133 Pa) for 120 seconds.

Referring to FIG. 43B, it can be seen in the illustrated example that the foregoing rate of concentration variation takes a very large value in the case the concentration distribution parameter σ1 is less than 80 mm. Further, it can be seen that the rate of concentration variation takes the value of about 40% in the event the concentration distribution parameter σ1 is 150 mm or more. Furthermore, it can be seen that there exists a point in which the rate of concentration variation takes a minimum value of 2-3% in the case the concentration distribution parameter σ1 takes the value of about 80 mm. From the relationship of FIG. 43A, it can be seen that the Ar gas flow rate corresponding to the foregoing concentration distribution parameter σ1 minimizing the rate of concentration variation is about 1.8SLM.

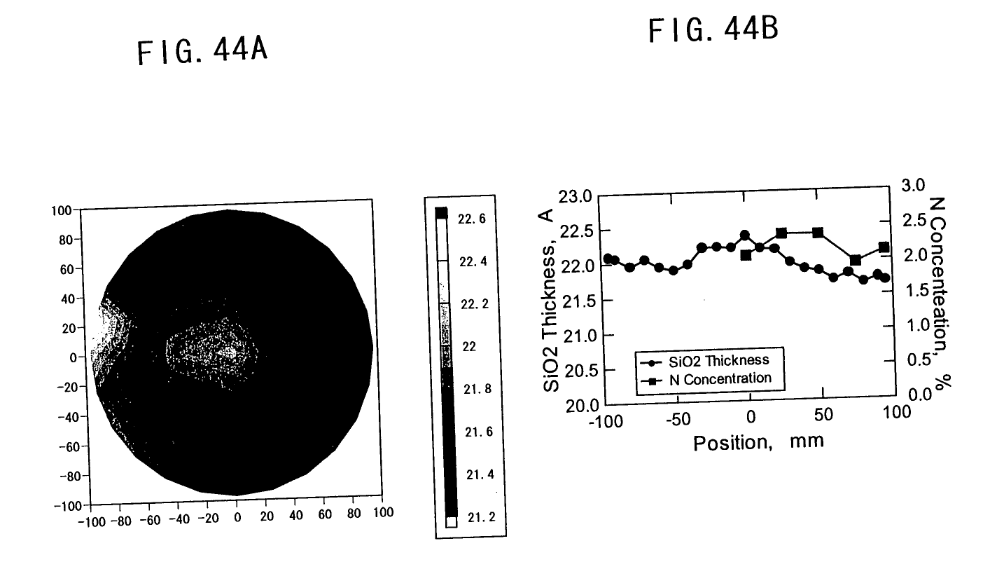

FIGS. 44A and 44B show the thickness distribution of the oxynitride film formed for the case the oxide film on the substrate W is nitrided under the foregoing condition in which the rate of concentration variation of the nitrogen radicals on the substrate W becomes minimum, wherein FIG. 44A shows the thickness distribution obtained by ellipsometry, while FIG. 44B shows the thickness distribution profile of the oxynitride film thus obtained and the distribution profile of the nitrogen concentration. In FIG. 44B, it should be noted that the distribution of the nitrogen concentration is the one obtained by XPS analysis.

Referring to FIG. 44A, the thickness distribution of the oxynitride film corresponds to the distribution of FIG. 42A and it can be seen from the thickness distribution profile and the nitrogen concentration profile of FIG. 44B, there is formed an oxynitride film of uniform composition on the substrate.

Thus, according to the substrate processing apparatus of the present embodiment, it becomes possible to form a uniform oxynitride film on the surface of the substrate held in the processing vessel in the rotating stated, by forming a nitrogen radical flow in the processing vessel so as to flow along the surface of the substrate and by optimizing the velocity of the nitrogen radical flow.

Further, it should be noted that the substrate processing apparatus 110 of the present embodiment can also conduct oxygen plasma processing by supplying oxygen to the plasma radical source 93.

[Eleventh Embodiment]

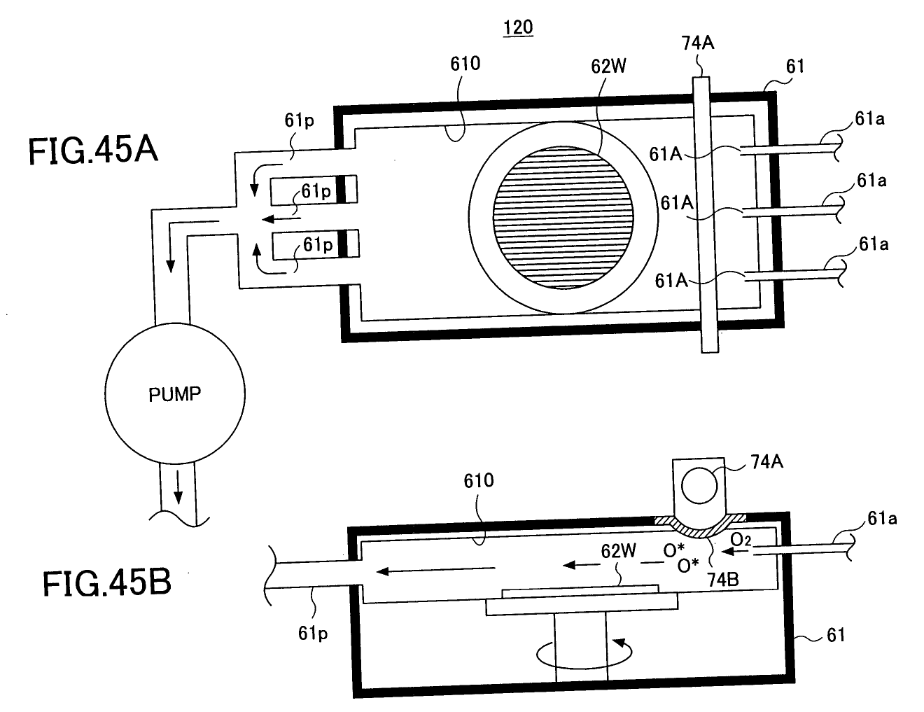

FIGS. 45A and 45B show the construction of a substrate processing apparatus 120 according to an eleventh embodiment of the present invention respectively in a plan view and in a cross-sectional view, wherein those parts corresponding to the parts explained previously are designated by the same reference numerals and the description thereof will be omitted.

Referring to FIGS. 45A and 45B, the reaction vessel 61 is evacuated at a first end thereof via an evacuation port 61p connected to a pump 61P, and an oxygen gas in a line 61a is supplied to the other end via a nozzle 61A. Further, there is provided an optical window 74B on the processing vessel 61 at a side offset to the end where the nozzle 61A is provided with respect to the substrate 62W, and a linear ultraviolet source 74A is provided in correspondence to the optical window 74B.

In the substrate processing apparatus 120 of FIGS. 45A and 45B, it should be noted that there is provided an internal reactor 610 as the passage of the process gas, and the oxygen gas introduced from the nozzle 61A is caused to flow through the inner reactor 610 to the evacuation port 61p along the surface of the substrate W exposed at the bottom part of the internal reactor 610, wherein the oxygen gas thus introduced is activated as it passes through the region right underneath the optical window 74B by the ultraviolet source 74A, and oxygen radicals O* are formed as a result. Thereby, it becomes possible to form a uniform oxide film on the surface of the substrate 62W by rotating the substrate 62W similarly to the previous embodiment and by optimizing the velocity of the oxygen gas at the nozzle 61A.

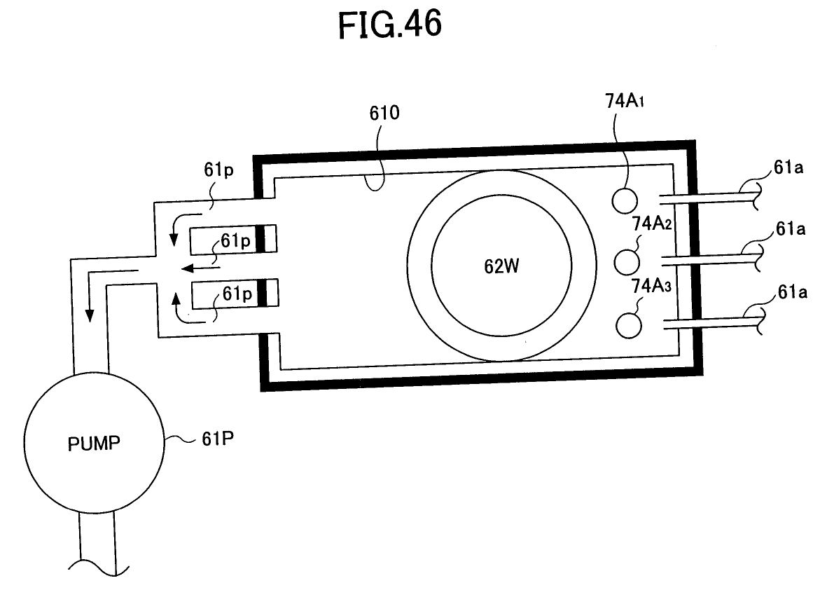

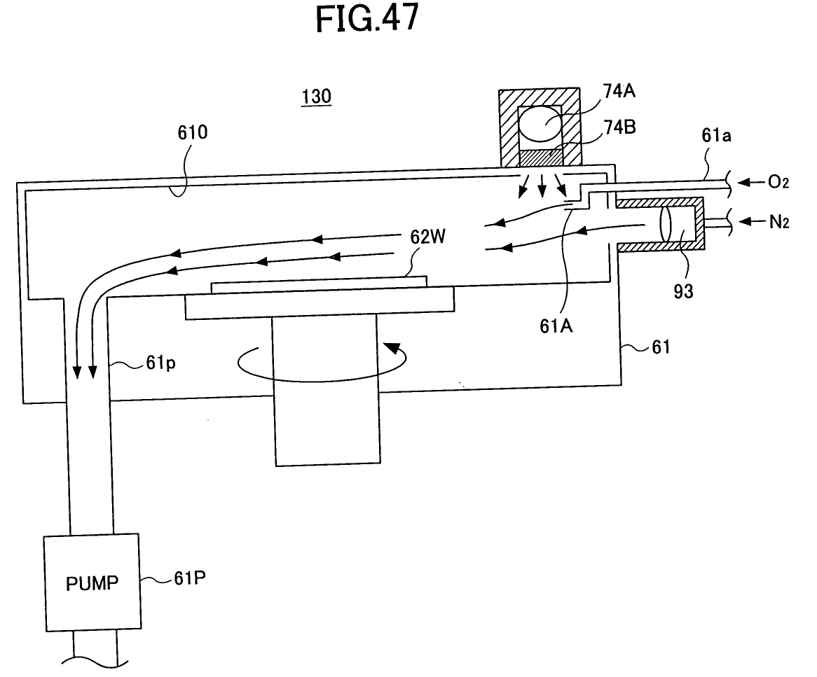

FIG. 46 shows a modification in which the ultraviolet source 74A in the substrate processing apparatus 120 of FIG. 45 is replaced with a plurality of ultraviolet sources 74A₁-74A₃.

In the present embodiment, too, it becomes possible to form a uniform oxide film on the surface of the substrate 62W by optimizing the velocity of the oxygen gas at the nozzle 61A.

[Twelfth Embodiment]

FIG. 47 shows the construction of a substrate processing apparatus 130 according to a twelfth embodiment of the present invention, wherein those parts of FIG. 47 corresponding to the parts described previously are designated by the same reference numerals and the description thereof will be omitted.

Referring to FIG. 47, it can be seen that the evacuation port 61p connected to the pump 61P is provided at the first end of the processing vessel 61 and the nozzle 61A connected to the oxygen gas supply line 61a is provided at the second, opposite end. Further, the plasma source 93 supplied with a nitrogen gas and an inert gas and forming nitrogen plasma is provided at the second end.

The substrate 62 is exposed at the bottom part of the inner reactor 610 provided inside the processing vessel 61, and the oxygen gas supplied from the nozzle 61A or the nitrogen radicals or oxygen radicals supplied from the plasma source 93 are caused to flow through the inner reactor 610 along the surface of the substrate 62W from the first end to the second end and discharged from the evacuation port 61p. Further, it can be seen that the ultraviolet source 74A is provided on the processing vessel 61 at the side closer to the second end with respect to the substrate 62W, and thus, it becomes possible to excite oxygen radicals in the oxygen gas flow by irradiating the ultraviolet radiation formed by the ultraviolet source 74A through the optical window 74B.

Thus, the substrate processing apparatus 130 of FIG. 47 is capable of conducting the nitridation processing and oxidation processing of the substrate 62W flexibly according to the needs, and thus, it becomes possible to unify the processing chamber 43 and the processing chamber 44A in the event the substrate processing apparatus 130 is applied to the cluster-type semiconductor fabrication apparatus explained with reference to FIG. 12.

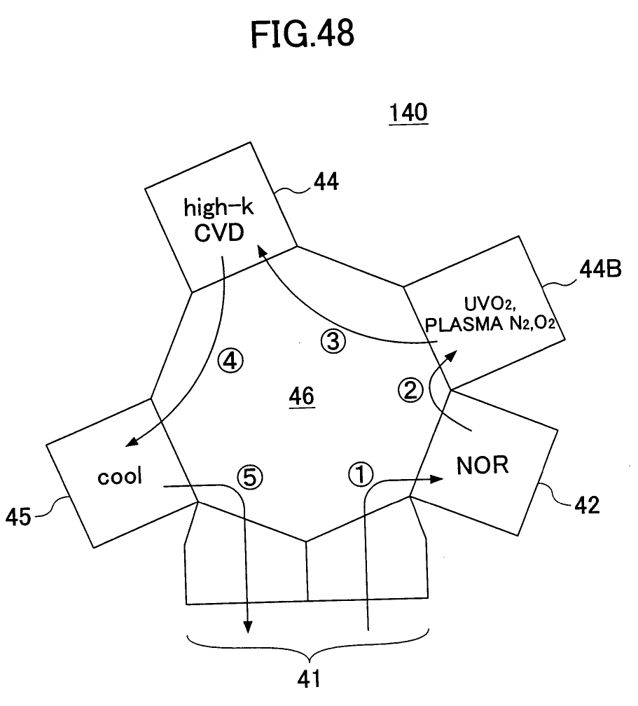

FIG. 48 shows the construction of a cluster-type substrate processing system 140 in which the CVD processing chamber 44 for forming the high-K dielectric film of FIG. 11 is combined with a processing chamber 44B in which the processing chamber 43 and the processing chamber 44A are unified. In FIG. 48, it should be noted that those parts corresponding to the parts explained previously are designated by the same reference numerals and the description thereof will be omitted.

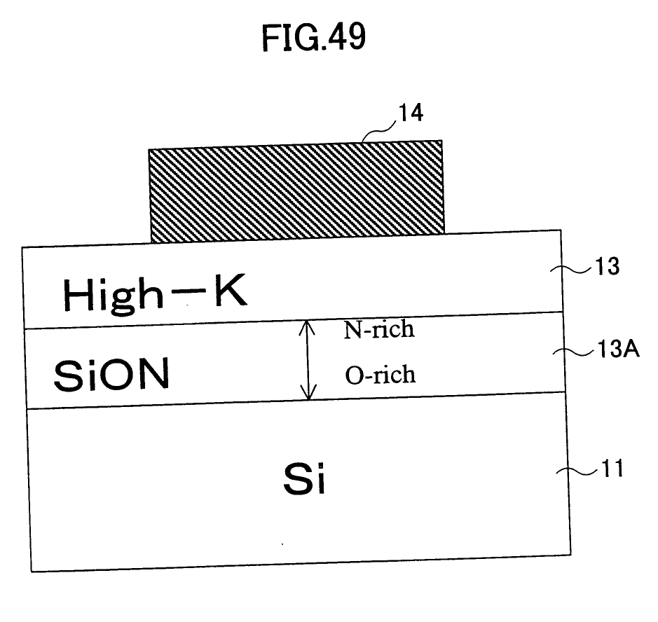

Referring to FIG. 48, it is possible to conduct the ultraviolet-activated radical oxidation processing, plasma-activated radical oxidation processing, plasma-activated radical nitridation processing or a radical oxynitridation processing that combines any of these in the processing chamber 44B according to the needs, and thus, it becomes possible to fabricate a semiconductor device having a gate insulation film of laminated structure as shown in FIG. 49 in which the SiON film 13A having a compositional gradient similarly to the case of FIG. 13 and the high-K dielectric film 13 explained with reference to FIG. 1 are laminated and in which the gate electrode 14 is formed on such a gate insulation film.

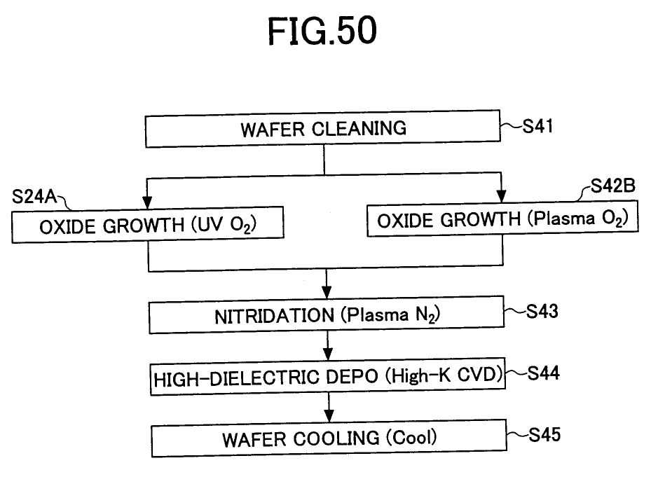

FIG. 50 is a flowchart showing the process flow of fabricating a semiconductor device of FIG. 49 by using the cluster-type substrate processing system 140 of FIG. 48.

Referring to FIG. 50, the Si substrate 11 is cleaned in the preprocessing chamber 42 in the first step 41 and native oxide film is removed from the substrate surface. The Si substrate 11 thus removed the native oxide film is then forwarded tot eh substrate processing apparatus 130 in the processing chamber 44B as the substrate 62W.

In the processing chamber 44B, the process proceeds to the step 42A or step 42B, wherein an oxygen gas is introduced into the inner reactor 610 of the substrate processing apparatus 130 from the line 61a in the event the process has proceeded to the step 42A, and the ultraviolet source 74A is activated. Thereby, the oxygen radicals formed as a result of ultraviolet-activation of the oxygen gas form an oxide film on the surface of the Si substrate 11.

In the case the process has proceeded to the step 42B, on the other hand, the plasma source 93 is activated in the processing 44B, oxygen radicals are formed by supplying an oxygen gas to the plasma source 93 or by supplying an oxygen gas and an inert gas such as Ar to the foregoing plasma source 93. Thereby, the oxygen radicals form an oxide film on the surface of the Si substrate 11.

Next, the process proceeds to the step 43 and a nitrogen gas is introduced into the plasma source 93 in place of the oxygen gas, and as a result, there are formed nitrogen radicals in the reactor 610. As a result of formation of such nitrogen radicals, nitrogen is introduced to the surface of the oxide film, and the oxide film is converted to the oxynitride film 13A shown in FIG. 13A.

Next, the substrate 11 is forwarded to the CVD chamber 44 for formation of the high-K dielectric gate insulation film 13 on the oxynitride film 13A, and thus, there is formed a high-K dielectric gate insulation film on the Si substrate 11.

Further, after a cooling process in the step 45, the substrate 11 is forwarded to an annealing step of the high-K dielectric gate insulation film and further to the process for formation of the gate electrode.

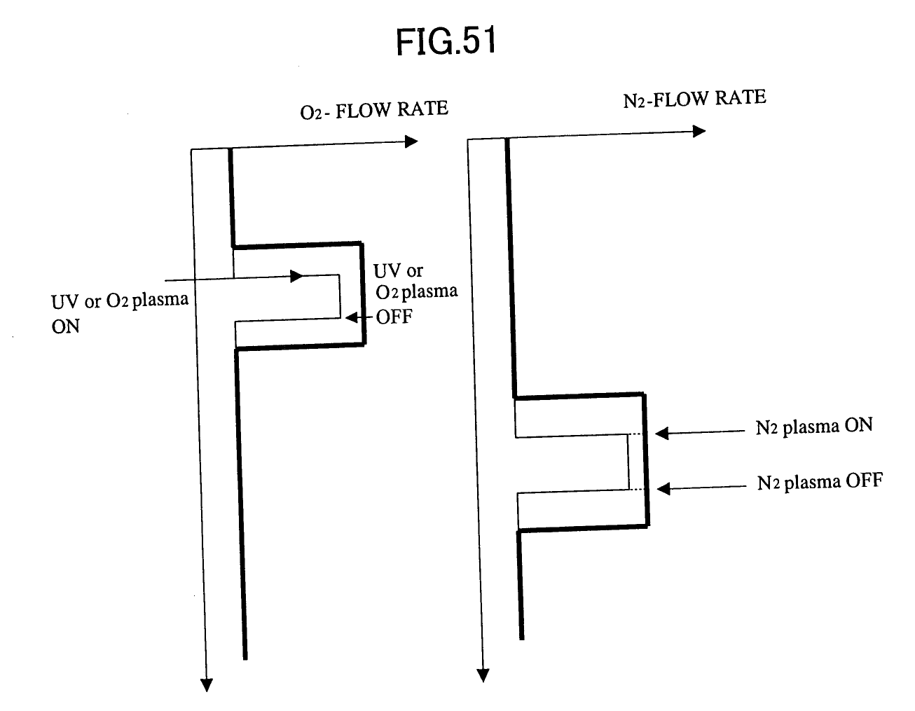

FIG. 51 is a diagram showing the timing of supplying the oxygen gas and the nitrogen gas to the substrate processing apparatus 130 in the formation step of the oxynitride film corresponding to the step 42A or 42B or the step 43 of FIG. 50, in superposition with the drive timing of the ultraviolet source 74A or the plasma source 93.

Referring to FIG. 51, an oxygen gas is introduced into the inner reactor 610 of the substrate processing apparatus 130 in correspondence to the oxide film formation step 42A or 42B, and the ultraviolet source 74A or the plasma source 93 is activated. Further, by deactivating the ultraviolet source 74A or the plasma source 93, the formation of the oxide film is terminated. Thereafter, supply of the oxygen gas is terminated.

After the termination of the step for forming the oxide film in the step 42A or step 42B, a nitrogen gas is introduced into the inner reactor 610 in correspondence to the step 43, and the plasma source 93 is activated further. Further, by deactivating the plasma source 93, the nitridation process of the oxide film is terminated. Thereafter, the supply of the nitrogen gas is terminated. Here, it should be noted that simultaneous progress of the plasma nitridation process and plasma oxidation process is avoided by removing the residual oxygen in the substrate processing apparatus 130 by conducting vacuum evacuation process and nitrogen purging process repeatedly before starting the step 43. As a result, the problem of increase of the thickness of the underlying film in the step 43 is avoided.

Thus, by using the substrate processing apparatus 130 explained with reference to FIG. 47, it becomes possible to conduct the foregoing radical oxidation processing and radical nitridation processing of the substrate in the same substrate processing in continuation, without exposing the substrate to the air in the present embodiment. In the case of the cluster-type substrate processing system, it becomes possible to conduct the foregoing radical oxidation processing and the radical nitridation processing without returning the substrate to the transfer chamber 46. Thereby, the efficiency of substrate processing is improvised and the risk of contamination of the substrate is reduced. As a result, the yield of production of the semiconductor device is improved.

Further, the present invention is not limited to the specific embodiments explained heretofore, but various variations and modifications may be made within the scope of the invention as set forth in the claims.

### INDUSTRIAL APPLICABILITY

According to the present invention, it becomes possible to optimize the ultraviolet radiation from an ultraviolet source to the substrate surface in a substrate processing apparatus designed for forming an oxide film between a substrate and a high-K dielectric gate insulation film, by providing: gas supplying means supplying a process gas containing oxygen to a substrate surface; an ultraviolet radiation source activating the process gas by irradiating the substrate surface with the ultraviolet radiation; and an optical source moving mechanism moving the ultraviolet source over the substrate surface at a predetermined height. As a result, it becomes possible to form an extremely thin oxide film on the substrate with a uniform thickness. Further, the present invention enables formation of an insulation film of uniform film quality in a substrate processing of apparatus using remote plasma by optimizing of the state of the remote plasma source.

Further, according to the present invention, it becomes possible to conduct a uniform substrate processing on a substrate surface by forming a flow of radicals from the first side to the second side along the surface of a rotating substrate, and by optimizing the flow velocity of the radical flow.

Thus, according to the present invention, it becomes possible to form an extremely thin insulation film on a substrate surface with a uniform thickness. By forming a high-K dielectric gate insulation film, for example, on such an extremely thin and uniform insulation film, it becomes possible to realize a semiconductor device operating at high speed.

1. A method of fabricating a semiconductor device having a structure in which an oxide film and a high-K dielectric gate insulation film are laminated on a substrate,
characterized in that said oxide film is formed by the steps of:
supplying a process gas containing oxygen to a surface of said substrate;
activating said process gas by irradiating said surface of said substrate with ultraviolet radiation from an ultraviolet radiation source; and
moving said substrate and said ultraviolet source relatively with each other.

2. The method of fabricating a semiconductor device as claimed in claim 1, wherein said oxide film has a thickness in the range of 0.3-1.5 nm.

3. The method of fabricating a semiconductor device as claimed in claim 1, wherein said oxide film has a thickness of about 1.0 nm or less.

4. The method of fabricating a semiconductor device as claimed in claim 1, wherein said oxide film has a thickness of about 5-6 molecular layers or less.

5. The method of fabricating a semiconductor device as claimed in claim 1, wherein said oxide film has a thickness of about 3 molecular layers or less.

6. The method of fabricating a semiconductor device as claimed in claim 1, wherein said process gas is selected from one or more of the group consisting of O₂, O₃, N₂O and NO.

7. The method of fabricating a semiconductor device as claimed in claim 1, wherein said step of moving said substrate and said ultraviolet source relatively with each other comprises the step of causing a back and forth movement in said ultraviolet source on said substrate surface.

8. The method of fabricating a semiconductor device as claimed in claim 1, wherein said step of moving said substrate and said ultraviolet source relatively with each other comprises the step of causing a rotating movement in said ultraviolet source on said surface of said substrate with respect to said substrate.

9. The method of fabricating a semiconductor device as claimed in claim 1, wherein said step of moving said substrate and said ultraviolet source relatively with each other comprises the step of causing a rotating movement in said substrate on said surface of said substrate with respect to said ultraviolet source.

10. The method of fabricating a semiconductor device as claimed in claim 8, wherein said step of moving said substrate and said ultraviolet source relatively with each other further comprises the step of causing a back and forth movement in said ultraviolet source on said surface of said substrate in a predetermined direction determined by a rotating angle between said ultraviolet source and said substrate.

11. The method of fabricating a semiconductor device as claimed in claim 1, wherein said step-of moving said substrate and said ultraviolet source relatively with each other comprises the step of causing said ultraviolet source to scan over said surface of said substrate in first and second directions.

12. The method of fabricating a semiconductor device as claimed in claim 1, wherein said step of moving said substrate and said ultraviolet source is conducted in a limited region of said substrate, and wherein said limited region is chosen such that a film thickness variation of said oxide film on said surface of said substrate becomes minimum.

13. The method of fabricating a semiconductor device as claimed in claim 1, wherein said step of activating said process gas is conducted by driving said ultraviolet source with an energy set such that a film thickness variation of said oxide film on said surface of said substrate becomes minimum.

14. A substrate processing apparatus for forming an oxide film between a substrate and a high-K dielectric gate insulation film, characterized by:
gas supplying means for supplying a process gas containing oxygen to a surface of said substrate;
an ultraviolet source for activating said process gas by irradiating said surface of said substrate with ultraviolet radiation; and
an optical source moving mechanism for moving said ultraviolet source at a predetermined height above said surface of said substrate.

15. The substrate processing apparatus as claimed in claim 14, wherein said substrate processing apparatus further comprises a control apparatus controlling said optical source moving mechanism according to a program such that said ultraviolet source moves over a specified region of said surface of said substrate, and wherein said control apparatus selects said specified region such hat a film thickness variation of said oxide film on aid surface of said substrate becomes minimum.

16. The substrate processing apparatus as claimed in claim 15, wherein said program is determined by a process of seeking for the region in said substrate processing apparatus in which said film thickness variation of said oxide film becomes minimum.

17. The substrate processing apparatus as claimed in claim 14, wherein said substrate processing apparatus further comprises a control apparatus driving said ultraviolet source, and wherein said control apparatus controls a radiation dose of said ultraviolet radiation formed by said ultraviolet source according to a program such that a film thickness variation of said oxide film on said surface of said substrate becomes minimum.

18. The substrate processing apparatus as claimed in claim 17, wherein said program is determined by a process of seeking for the ultraviolet radiation dose that minimizes said film thickness variation of said oxide film in said substrate processing apparatus.

19. The substrate processing apparatus as claimed in claim 14, wherein said gas supplying means comprises a showerhead of a material transparent to said ultraviolet radiation and disposed between said ultraviolet source and said substrate.

20. The substrate processing apparatus as claimed in claim 14, wherein said gas supplying means comprises a plurality of nozzles supplying said process gas to said substrate surface from a periphery of said substrate.

21. The substrate processing apparatus as claimed in claim 14, wherein said ultraviolet source comprises a linear optical source.

22. The substrate processing apparatus as claimed in claim 14, wherein said ultraviolet source comprises a point-like optical source.

23. The substrate processing apparatus as claimed in claim 14, wherein said ultraviolet source comprises or more optical sources.

24. The substrate processing apparatus as claimed in claim 14, wherein said ultraviolet source includes an evacuation line for evacuating atmosphere in the vicinity of said ultraviolet source.

25. The substrate processing apparatus as claimed in claim 14, wherein said ultraviolet source includes a gas supply line for supplying an inert ambient to a region in the vicinity of said ultraviolet source.

26. A substrate processing system, characterized by:
a film formation apparatus forming a high-K dielectric film on a substrate;
a substrate processing apparatus forming an insulation film on a surface of said substrate such that said insulation film is sandwiched between said high-K dielectric film and said substrate; and
a vacuum transportation chamber provides so as to connect said deposition apparatus and said substrate processing apparatus by a vacuum ambient, said vacuum transportation chamber having a substrate transportation mechanism;
said substrate processing apparatus comprising:
gas supplying means for supplying a process gas containing oxygen to said surface of said substrate;
an ultraviolet source activating said process gas by irradiating said surface of said substrate with ultraviolet radiation; and
an optical source moving mechanism for moving said ultraviolet source at a predetermined height over said surface of said substrate.

27. The substrate processing system as claimed in claim 26, further comprising a cooling apparatus cooling said substrate in a manner such that said cooling apparatus is connected to said vacuum transportation chamber.

28. The substrate processing system as claimed in claim 26, further comprising a preprocessing apparatus conducting preprocessing on said substrate in a manner such that said preprocessing chamber is connected to said vacuum transportation chamber.

29. The substrate processing system, characterized by:
a substrate processing apparatus forming an insulation film on a substrate surface;
a plasma nitridation processing apparatus conducting a plasma nitridation processing on said substrate surface; and
a vacuum transportation chamber connecting said deposition apparatus and said substrate processing apparatus by a vacuum ambient, said vacuum transportation chamber including a substrate transportation mechanism,
said substrate processing apparatus comprising:
gas supplying means for supplying a process gas containing oxygen to said substrate surface;
an ultraviolet source activating said process gas by irradiating said substrate surface with ultraviolet radiation; and
an optical source moving mechanism for moving said ultraviolet source over said substrate surface at a predetermined height.

30. A film formation method for forming an insulation film on a substrate, characterized by the steps of:
supplying a process gas to one or more radical sources;
forming active radicals from said process gas in each of said one or more radical sources;
supplying said active radicals to a surface of said substrate; and
forming an insulation film by a reaction of said active radicals on said surface of said substrate,
said step of forming said active radicals being conducted while changing a state of each of said one or more radical sources,
said method further comprising the steps of:
obtaining an optimum state for each of said one or more radical sources based on a state of said insulation film, said optimum state minimizing a variation of film state within said insulation film; and
forming an insulation film on said surface of said substrate by setting the state of each of said one or more radical sources to said optimum state.

31. The method of forming an insulation film as claimed in claim 30, wherein each of said one or more radical sources comprises a plasma source and an opening formed with a distance from said plasma source for passing said active radicals therethrough.

32. The method of forming an insulation film as claimed in claim 30, wherein said optimum state is chosen so as to minimize a film thickness variation of said insulation film for each of said one or more radical sources.

33. The method of forming an insulation film as claimed in claim 30, wherein said optimum state is chosen so as to minimize a compositional variation of said insulation film for each of said one or more radical sources.

34. The method of forming an insulation film as claimed in claim 30, wherein said step of changing the sate for each of said one or more radical sources comprises the step of displacing a location of said radical source relatively with respect to said substrate for each of said one or more radical sources.

35. The method of forming an insulation film as claimed in claim 30, wherein said step of changing the state for each of said one or more radical sources comprises the step of changing a driving power of said plasma sources.

36. The method of forming an insulation film as claimed in claim 30, wherein said step of changing the state of said one or more radical sources comprises the step of changing an angle of said radical sources with respect to said substrate.

37. The method of forming an insulation film as claimed in claim 30, wherein said step of forming said insulation film is conducted while rotating said substrate.

38. A substrate processing apparatus for forming an insulation film on a substrate, characterized by:
a processing chamber having a stage for holding a substrate;
a plurality of radical sources provided adjacent to said processing chamber at respective locations, each of said radical sources being supplied with a process gas and supplying active radicals into said processing chamber; and
a radical source setup part setting up a state of said plurality of radical sources,
said radical source setup part setting up said plurality of radical sources to respective state such that said insulation film has a uniform film state.

39. The substrate processing apparatus as claimed in claim 38, wherein each of said plurality of radical sources comprises a plasma source supplied with said process gas, and an opening formed with a distance from said plasma source of supplying said active radicals to said processing chamber therethrough.

40. The substrate processing apparatus as claimed in claim 38, wherein said radical source setup part sets up said states of said plurality of radical sources such that said insulation film has a uniform thickness.

41. The substrate processing apparatus as claimed in claim 38, wherein said radical source setup part sets up said states of said plurality of radical sources such that said insulation film has a uniform composition.

42. The substrate processing apparatus as claimed in claim 38, wherein said radical source setup part holds each of said plurality of radical sources movably with respect to said processing chamber.

43. The substrate processing apparatus as claimed in claim 38, wherein said radical source setup part holds each of said plurality of radical sources such that an angle with respect to said substrate can be changed.

44. The substrate processing apparatus as claimed in claim 39, wherein said radical source setup part includes a drive circuit driving said plasma source, and wherein said drive circuit drives said plasma source such that said insulation film has a uniform film state.

45. A substrate processing apparatus, characterized by:
a processing vessel including a stage for holding a substrate;
a process gas inlet provided at a first end of said processing vessel;
an evacuation opening formed on said processing vessel at a second end opposing said first end with respect to said stage;
a radical source formed in said processing vessel at a side closer to said first end with respect to said stage; and
a rotating mechanism rotating said stage.

46. The substrate processing apparatus as claimed in claim 45, wherein said radical source comprises a plasma generator.

47. The substrate processing apparatus as claimed in claim 46, wherein said plasma generator is provided on a sidewall surface of said processing vessel.

48. The substrate processing apparatus as claimed in claim 47, wherein said plasma generator constitutes said process gas inlet.

49. The substrate processing apparatus as claimed in claim 45, wherein said radical generator comprises an ultraviolet source.

50. The substrate processing apparatus as claimed in claim 49, wherein said ultraviolet source is provided between said process gas inlet and said substrate on said stage, said ultraviolet source introducing ultraviolet radiation into said processing vessel through an optical window formed on said processing vessel.

51. The substrate processing apparatus as claimed in claim 49, wherein said ultraviolet source comprises a linear optical source.

52. The substrate processing apparatus as claimed in claim 49, wherein said ultraviolet source comprises a plurality of point-like optical sources.

53. The substrate processing apparatus as claimed in claim 45, wherein said processing vessel includes therein an internal reactor defining a passage of said process gas, and wherein said substrate is exposed at a bottom surface of said internal reactor in the state said substrate is held on said stage.

54. The substrate processing apparatus as claimed in claim 45, wherein said radical source comprises a plasma generator and an ultraviolet source.

55. The substrate processing apparatus as claimed in claim 54, wherein said plasma generator is provided on a sidewall surface of said processing vessel and said ultraviolet source is provided on said processing vessel between said process gas inlet and said substrate on said stage, said ultraviolet source introducing ultraviolet radiation into said processing vessel through an optical window formed on said processing vessel.

56. A substrate processing method, comprising the steps of:
rotating a substrate in a processing chamber in which said substrate is held;
forming a radical flow in said processing vessel such that said radical flow flows along a surface of said substrate from a first side to a second side; and
processing said surface of said substrate by said radical flow.

57. The substrate processing method as claimed in claim 56, wherein said step of forming said radical flow is conducted such that there is formed a concentration gradient of radicals in said radical flow from said first side to said second side.

58. The substrate processing method as claimed in claim 56, wherein said step of forming said radical flow is conducted by supplying radicals under a condition that said supplied radicals are annihilated before said radicals reach said second side across a center of said substrate.

59. The substrate processing method as claimed in claim 56, wherein said step of forming said radical flow includes the step of activating a process gas flow by plasma.

60. The substrate processing method as claimed in claim 56, wherein said step of forming said radical flow includes the step of activating a process gas flow by ultraviolet radiation.

61. The substrate processing apparatus as claimed in claim 45, wherein said process gas inlet includes a plurality of process gas inlet openings.

62. The substrate processing apparatus as claimed in claim 52, wherein said process gas inlet includes a plurality of process gas inlet openings, and said plurality of point-like optical sources are provided on a flow path of respective process gas flows introduced from said plurality of process gas inlet openings.
